(19) United States
(12) Patent Application Publication
(10) Pub. No.: US 2025/0292998 A1
(43) Pub. Date: Sep. 18, 2025

(54) MATCHING CIRCUIT AND PLASMA PROCESSING APPARATUS

(71) Applicant: Tokyo Electron Limited, Tokyo (JP)

(72) Inventor: Masaki HIRAYAMA, Tokyo (JP)

(21) Appl. No.: 19/073,541

(22) Filed: Mar. 7, 2025

(30) Foreign Application Priority Data
Mar. 13, 2024 (JP) 2024-038953

(51) Int. Cl. H01J 37/32

(52) U.S. Cl. CPC H01J 37/32183

(57) ABSTRACT

A matching circuit includes: a plurality of reactance elements connected to a supply line for supplying radio-frequency power for plasma generation; a plurality of relays, wherein each of the plurality of relays includes a relay switch having a first contact connected to a corresponding reactance element among the plurality of reactance elements and a second contact connected to a ground, and a relay coil; at least one diode connected in parallel to the relay coil of each of the relays and configured to rectify a radio-frequency current flowing through a parasitic capacitance between the relay coil and the corresponding reactance element; and at least one capacitor connected in parallel to the relay coil of each of the relays and configured to generate a direct-current (DC) voltage applied to the relay coil in response to a current generated by rectifying the radio-frequency current with the at least one diode.

### CROSS-REFERENCE TO RELATED APPLICATION

This application is based upon and claims the benefit of priority from Japanese Patent Application No. 2024-038953, filed on Mar. 13, 2024, the entire contents of which are incorporated herein by reference.

### TECHNICAL FIELD

The present disclosure relates to a matching circuit and a plasma processing apparatus.

### BACKGROUND

A plasma processing apparatus is used in plasma processing for a substrate. The plasma processing apparatus includes a chamber, a radio-frequency power supply, and a matcher. The radio-frequency power supply is configured to generate radio-frequency power so as to generate plasma from a gas inside the chamber. The matcher is configured to match an impedance of a load to an output impedance of the radio-frequency power supply. The matcher of the plasma processing apparatus disclosed in Patent Document 1 includes a plurality of capacitors and a plurality of switching elements, and is configured to adjust a variable capacitance of the matcher depending on the open or closed state of the plurality of switching elements.

### PRIOR ART DOCUMENT

### Patent Document

Patent Document 1: Japanese Laid-Open Patent Publication No. 2022-078495

### SUMMARY

According to one embodiment of the present disclosure, a matching circuit includes: a plurality of reactance elements connected to a supply line for supplying radio-frequency power for plasma generation; a plurality of relays, wherein each of the plurality of relays includes a relay switch having a first contact connected to a corresponding reactance element among the plurality of reactance elements and a second contact connected to a ground, and a relay coil; at least one diode connected in parallel to the relay coil of each of the plurality of relays and configured to rectify a radio-frequency current flowing through a parasitic capacitance between the relay coil and the corresponding reactance element; and at least one capacitor connected in parallel to the relay coil of each of the plurality of relays and configured to generate a direct-current (DC) voltage applied to the relay coil in response to a current generated by rectifying the radio-frequency current with the at least one diode.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram showing a plasma processing apparatus according to one exemplary embodiment.

FIG. 2 is a diagram showing a lower portion of a resonator of the plasma processing apparatus according to one exemplary embodiment.

FIG. 3 is a cross-sectional view showing a coupler according to one exemplary embodiment.

FIG. 4 is a cross-sectional view taken along line IV-IV in FIG. 3.

FIG. 5 is a cross-sectional view taken along line V-V in FIG. 3.

FIG. 6 is an admittance chart associated with the coupler according to one exemplary embodiment.

FIG. 7 is a diagram showing a matching circuit according to one exemplary embodiment.

FIG. 8 is a diagram showing a relay according to another exemplary embodiment.

FIG. 9 is a diagram showing a relay according to yet another exemplary embodiment.

FIG. 10 is a cross-sectional view showing a coupler according to another exemplary embodiment.

FIG. 11 is a cross-sectional view taken along line XI-XI in FIG. 10.

FIG. 12 is a diagram showing a plasma processing apparatus according to another exemplary embodiment.

FIG. 13 is a cross-sectional view showing a coupler according to yet another exemplary embodiment.

FIG. 14 is a cross-sectional view taken along line XIV-XIV in FIG. 13.

FIG. 15 is a cross-sectional view showing a coupler according to yet another exemplary embodiment.

FIG. 16 is a cross-sectional view taken along line XVI-XVI in FIG. 15.

FIG. 17 is a cross-sectional view showing a coupler according to yet another exemplary embodiment.

FIG. 18 is a cross-sectional view taken along line XVIII-XVIII in FIG. 17.

FIG. 19 is a table showing a relationship between an inductance and a state (open or closed state) of relay switches of a plurality of relays in the coupler according to yet another exemplary embodiment.

FIG. 20 is a diagram showing an exemplary configuration for detecting a failure of a plurality of relays that may be employed in couplers according to various exemplary embodiments.

### DETAILED DESCRIPTION

Various exemplary embodiments will now be described in detail with reference to the drawings, in which the same or corresponding parts will be designated by the same reference numerals. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

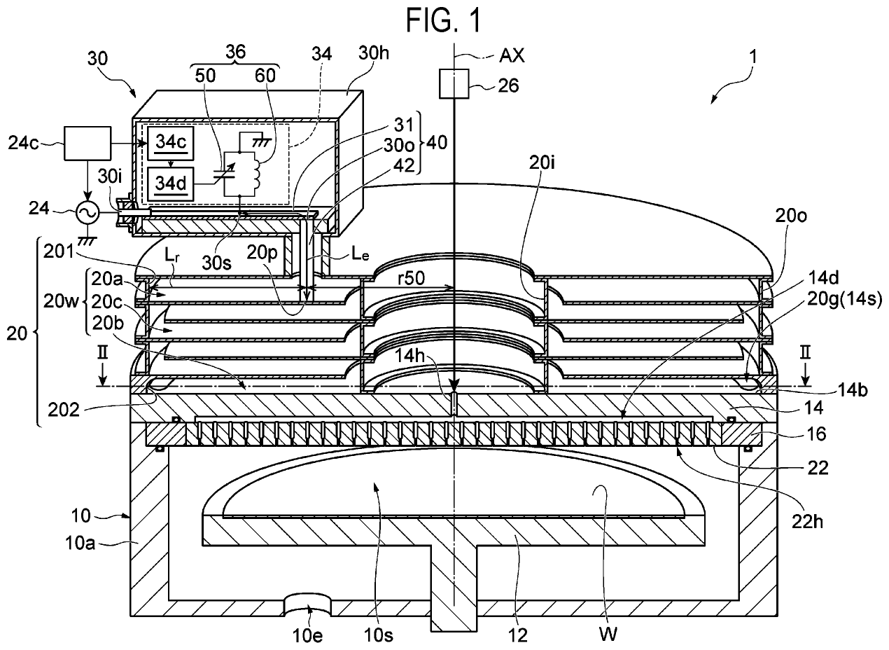

FIG. 1 is a diagram showing a plasma processing apparatus according to one exemplary embodiment. The plasma processing apparatus 1 shown in FIG. 1 includes a chamber 10, a substrate support 12, an introducer 16, a resonator 20, a radio-frequency power supply 24, and a coupler 30.

The chamber 10 provides a processing space 10s therein. In the plasma processing apparatus 1, a substrate W is processed inside the processing space 10s. The chamber 10 is made of a metal such as aluminum or the like, and is grounded. The chamber 10 has a sidewall 10a and is open at its upper end. The chamber 10 and the sidewall 10a may have a substantially cylindrical shape. The processing space 10s is provided inward of the sidewall 10a. A central axis of each of the chamber 10, the sidewall 10a, and the processing space 10s is defined as an axis AX. The chamber 10 may have a corrosion-resistant film on its surface. The corrosion-resistant film may be an yttrium oxide film, an yttrium oxide fluoride film, or a ceramic film including yttrium oxide, an yttrium fluoride, or the like.

A bottom portion of the chamber 10 provides an exhaust port 10e. The exhaust port 10e is connected to an exhaust device. The exhaust device may include a vacuum pump, such as a dry pump and/or a turbo-molecular pump, and an automatic pressure control valve.

The substrate support 12 is provided inside the processing space 10s. The substrate support 12 is configured to support the substrate W placed on its upper surface in an approximately horizontal posture. The substrate support 12 has a substantially disk-like shape. A central axis of the substrate support 12 is the axis AX.

In one embodiment, the plasma processing apparatus 1 may further include an upper electrode 14. The upper electrode 14 is provided above the substrate support 12 with the processing space 10s interposed therebetween. The upper electrode 14 is made of a conductor such as a metal (for example, aluminum) and has a substantially disk-like shape. A central axis of the upper electrode 14 is the axis AX. The upper electrode 14 constitutes an excitation electrode together with a shower plate 22, which will be described later.

The introducer 16 is provided to emit electromagnetic waves to a plasma generation region. In the plasma processing apparatus 1, the plasma generation region is a space existing in the processing space 10s and directly below the excitation electrode, that is, directly below the shower plate 22. In the plasma processing apparatus 1, the electromagnetic waves emitted from the introducer 16 to the plasma generation region excite the gas in the plasma generation region to generate plasma. The electromagnetic waves emitted from the introducer 16 to the plasma generation region may be radio-frequency waves such as VHF waves or UHF waves. The introducer 16 is formed of a dielectric material such as quartz, aluminum nitride, or aluminum oxide. In one embodiment, the introducer 16 is provided at a lateral end of the processing space 10s and extends in a circumferential direction around the axis AX. The introducer 16 may have a ring shape.

The resonator 20 includes a feeding portion 20p and a waveguide 20w. The feeding portion 20p is an inlet of the electromagnetic waves with respect to the waveguide 20w of the resonator 20. The electromagnetic waves are generated based on the radio-frequency power generated by the radio-frequency power supply 24. The radio-frequency power supply 24 is configured to be capable of changing a frequency of the radio-frequency power to be outputted. The electromagnetic waves are inputted to the feeding portion 20p of the resonator 20 via the coupler 30 described later. The resonator 20 resonates the electromagnetic waves inputted to the feeding portion 20p in the waveguide 20w and propagates the electromagnetic waves to the introducer 16. The electromagnetic waves are introduced from the introducer 16 to the plasma generation region. In one embodiment, the resonator 20 may be provided above the chamber 10 and on the upper electrode 14.

In one embodiment, the plasma processing apparatus 1 may further include the shower plate 22. The shower plate 22 may be made of a metal such as aluminum or the like. The introducer 16 extends to surround the shower plate 22. The introducer 16 and the shower plate 22 are arranged to close an opening at the upper end of the chamber 10. The shower plate 22 provides a plurality of gas holes 22h. The gas holes 22h extend in a thickness direction of the shower plate 22 (in a vertical direction) and penetrate the shower plate 22.

The shower plate 22 is provided below the upper electrode 14. The shower plate 22 extends above the plasma generation region. The shower plate 22 and the upper electrode 14 define a gas diffusion space 14d therebetween. A central axis of the gas diffusion space 14d may be the axis AX. The plurality of gas holes 22h of the shower plate 22 are connected to the gas diffusion space 14d. The upper electrode 14 also provides an inlet 14h. The inlet 14h may extend on the axis AX. The inlet 14h is connected to the gas diffusion space 14d. A gas supplier 26 is connected to the gas diffusion space 14d. The gas outputted from the gas supplier 26 is supplied to the processing space 10s via the inlet 14h, the gas diffusion space 14d, and the plurality of gas holes 22h.

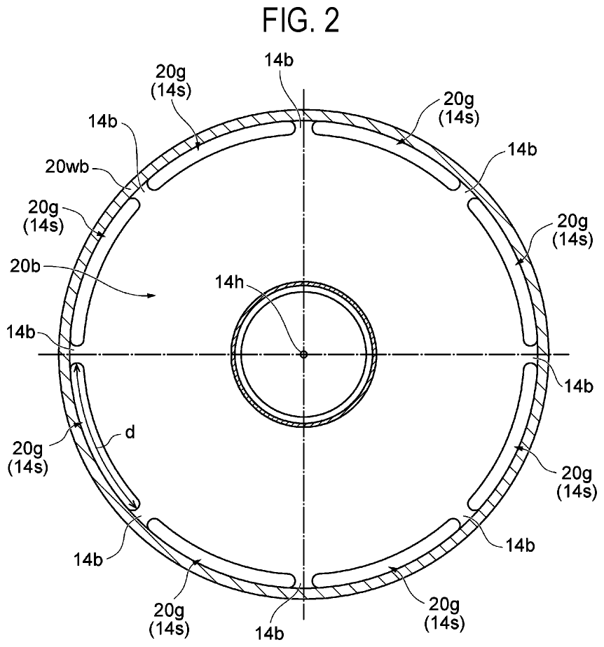

Reference will now be made to FIG. 2 together with FIG. 1. FIG. 2 is a diagram showing a lower portion of the resonator of the plasma processing apparatus according to one exemplary embodiment. FIG. 2 is a cross-sectional view taken along line II-II in FIG. 1. The waveguide 20w of the resonator 20 may provide a cavity surrounded by walls. Walls of the waveguide 20w are made of a material such as a metal or the like. The walls of the waveguide 20w may be made of an aluminum alloy, copper, nickel, stainless steel, or the like, and may be coated with a low resistance material such as silver, gold, rhodium, or the like.

The resonator 20 includes a first end 201 and a second end 202. The first end 201 and the second end 202 constitute one end and the other end of the waveguide 20w of the resonator 20. The second end 202 is electromagnetically coupled to the introducer 16.

In one embodiment, the wall of the resonator 20 may include an inner peripheral portion 20i and an outer peripheral portion 200. The inner peripheral portion 20i extends around the axis AX, which is the central axis thereof, and has a generally cylindrical shape. The outer peripheral portion 200 extends coaxially with the inner peripheral portion 20i around the axis AX. The outer peripheral portion 200 may have a generally cylindrical shape.

The waveguide 20w may have an alternately-folded layer structure between the inner peripheral portion 20i and the outer peripheral portion 200. The walls of the waveguide 20w may include a plurality of walls extending radially and circumferentially between adjacent layers of the layer structure and between the inner peripheral portion 20i and the outer peripheral portion 200. The walls may be annular plates.

Further, the waveguide 20w may include an upper portion 20a constituting the uppermost layer of the layer structure and a lower portion 20b constituting the lowermost layer of the layer structure. In addition, the layer structure may include an intermediate portion 20c between the upper portion 20a and the lower portion 20b. In this embodiment, the upper portion 20a may provide a first end 201, that is, an upper end, of the waveguide 20w at the outer peripheral portion 200. In this case, the first end 201 of the waveguide 20w extends along the circumferential direction around the axis AX. Further, the lower portion 20b may provide a second end 202, that is, a lower end, of the waveguide 20w at the outer peripheral portion 200. In this case, the second end 202 of the waveguide 20w extends along the circumferential direction around the axis AX.

The resonator 20 provides a plurality of gaps 20g near or along the second end 202. The gaps 20g are arranged in the circumferential direction around the axis AX. The electromagnetic waves resonated in the resonator 20 electromagnetically propagate to the introducer 16 via the gaps 20g.

In one embodiment, the upper electrode 14 provides a plurality of slots 14s as the plurality of gaps 20g, and includes a plurality of beams 14b. The slots 14s are arranged above the introducer 16. The slots 14s penetrate the upper electrode 14 along its thickness direction (vertical direction) and extend at a long length in the circumferential direction. The slots 14s are spaced apart from each other and arranged along the circumferential direction around the axis AX. The slots 14s may be arranged at equal intervals. The beams 14b are arranged alternately with the slots 14s along the circumferential direction around the axis AX. The beams 14b connect an inner portion and an outer portion of the upper electrode 14 to each other.

In the plasma processing apparatus 1, the resonance of electromagnetic waves occurs between the first end 201 and the second end 202. The electromagnetic waves resonated in the resonator 20 are supplied to the introducer 16 via the gaps 20g, that is, the slots 14s. The electromagnetic waves supplied to the introducer 16 are emitted from the introducer 16 to the plasma generation region.

In the resonator 20, a distance d of each of the gaps 20g in the circumferential direction may satisfy Formula (F1) below.

$$0.05 {λ}_{g} < d < 0.3 {λ}_{g} \qquad ( F1 )$$

In Formula (F1) above, λ_{g} is the wavelength of the electromagnetic waves in the waveguide 20w. When Formula (F1) is satisfied, the resonator 20 may supply a part of the electromagnetic waves propagating through the waveguide 20w to the introducer 16, and may have an appropriately large reflection coefficient of the electromagnetic waves at the other end of the resonator 20.

Further, a resonator length L₂₀ of the resonator 20 between the first end 201 and the second end 202 (a distance connecting the first end 201 and the second end 202 along the waveguide 20w) may satisfy Formula (F2) below.

$$( n - 0.2 ) {λ}_{g} / 2 < {L}_{20} < n {λ}_{g} / 2 \qquad ( F2 )$$

In Formula (F2) above, λ_{g} is the wavelength of the electromagnetic waves in the waveguide 20w. Further, n is an integer equal to or greater than 1. A reactance in the gaps 20g is inductive. Therefore, the resonator length L₂₀ may be set to a value slightly smaller than nλ_{g}/2 so as to satisfy Formula (F2) above.

The coupler 30 is connected between the radio-frequency power supply 24 and the resonator 20. The coupler 30 includes an input portion 30i, an output portion 300, and a supply line 31. The supply line 31 extends so as to connect the input portion 30i and the output portion 300 to each other. The radio-frequency power supply 24 is connected to the input portion 30i. The output portion 300 is connected to the feeding portion 20p via the supply line 42. That is, the supply line 42 connects the output portion 300 and the feeding portion 20p to each other.

In the plasma processing apparatus 1, the supply line 31 and the supply line 42 constitute a supply line 40. The supply line 40 is a distributed constant line extending from the input portion 30i to the feeding portion 20p via the coupler 30, and is a transmission line having a constant characteristic impedance. The constant characteristic impedance is, for example, 50Ω. The constant characteristic impedance may be 50Ω or less. In one embodiment, the supply line 31 in the coupler 30 may be configured as a microstrip line. In addition, the supply line 42 may be configured as a coaxial line.

The coupler 30 may further include a matching circuit 34. The matching circuit 34 is arranged inside a grounded housing 30h (for example, a metal housing). The matching circuit 34 includes a variable reactance portion 36 having a variable impedance. The variable reactance portion 36 is connected between a connection point 30s of the supply line 31 and the ground. The variable reactance portion 36 includes a capacitor 50 and/or an inductor 60. The matching circuit 34 further includes a drive circuit 34d and a control circuit 34c. The drive circuit 34d is composed of a circuit for changing an impedance of the variable reactance portion 36. The control circuit 34c is configured to control the drive circuit 34d. The control circuit 34c may include a programmable processor such as a CPU or an MPU, a programmable logic device such as a Field Programmable Gate Array (FPGA), or a dedicated circuit such as an Application Specific Integrated Circuit (ASIC).

In the plasma processing apparatus 1, a voltage Vₘ₀ in the supply line 40 when there is no reflection from a load is (2×Z₀×P)^{1/2}, where Z₀ is a characteristic impedance of the supply line 40, and P is incident power to the supply line 40. When the characteristic impedance Z₀ of the supply line 40 is 50Ω and the incident power P is 1 kW, the voltage Vₘ₀ is 316 V. Even if a total reflection occurs, the maximum voltage in the supply line 40 is twice the voltage Vₘ₀. Therefore, in the plasma processing apparatus 1, even if the total reflection occurs, it is possible to reduce the maximum voltage in the coupler 30 generated by the radio-frequency power transmitted in the coupler 30. Further, in the plasma processing apparatus 1, the variable reactance portion 36 is connected to the supply line 31 included in the supply line 40. Therefore, an element having a relatively small withstand voltage may be used as an element constituting the variable reactance portion 36. As a result, according to the plasma processing apparatus 1, the coupler 30 may be reduced in size. In addition, an element having a fast response speed may be used as the element in the matching circuit 34.

In one embodiment, the plasma processing apparatus 1 may further include a directional coupler and a power supply controller 24c. The directional coupler may be provided in the radio-frequency power supply 24 or between the radio-frequency power supply 24 and the input portion 30i. The power supply controller 24c may be configured with a programmable processor such as a CPU or an MPU, a programmable logic device such as an FPGA (Field Programmable Gate Array), or a dedicated circuit such as an ASIC (Application Specific Integrated Circuit).

The directional coupler outputs a signal reflecting a power level of a reflected wave of the radio-frequency power to the power supply controller 24c. The power supply controller 24c controls the radio-frequency power supply 24 or the matching circuit 34 in response to the signal from the directional coupler so as to reduce the power level of the reflected wave. The power supply controller 24c may control the radio-frequency power supply 24 to adjust a frequency of the radio-frequency power in order to reduce the power level of the reflected wave. Alternatively or additionally, the power supply controller 24c may communicate with the control circuit 34c to cause the matching circuit 34 to adjust the reactance of the variable reactance portion 36 in order to reduce the power level of the reflected wave.

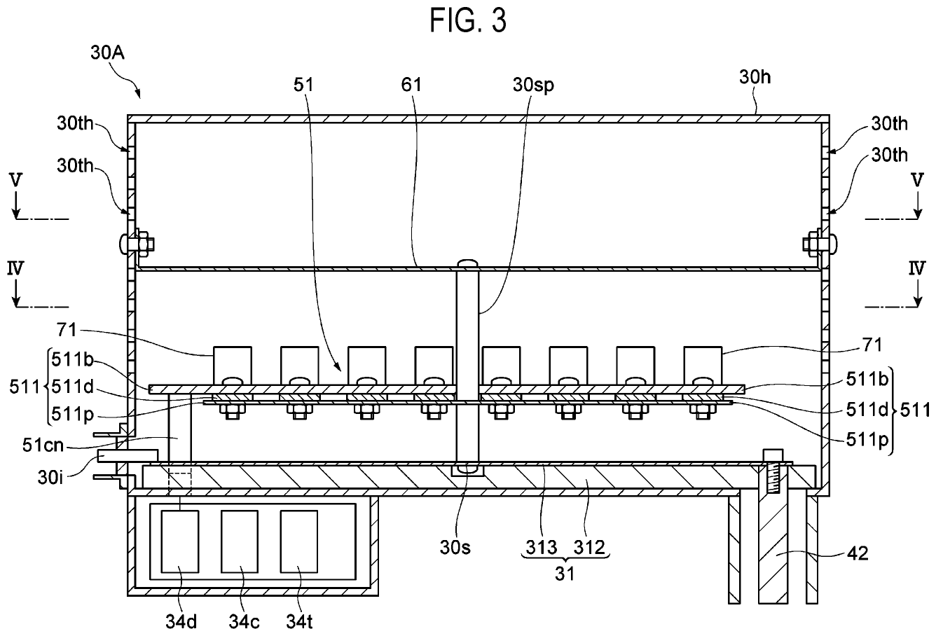

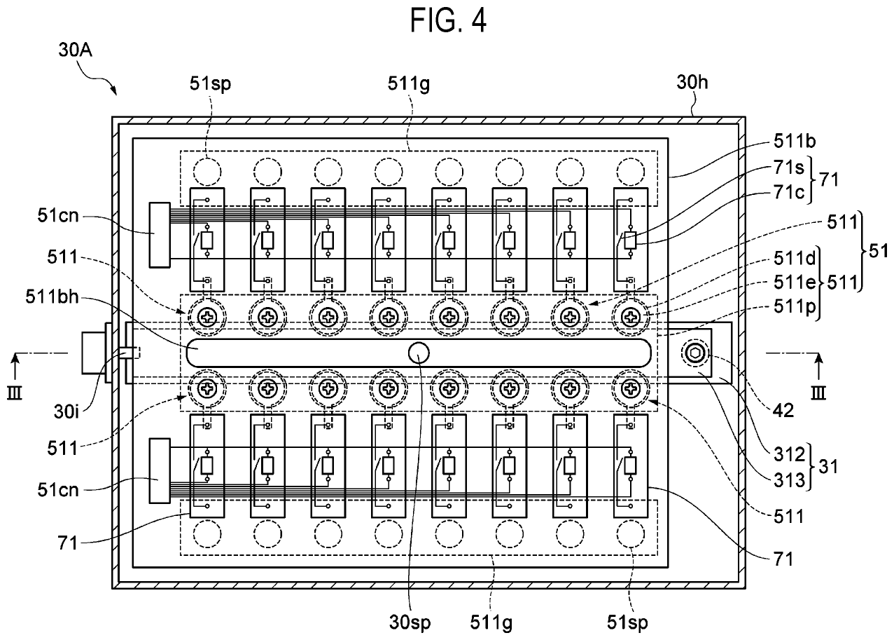

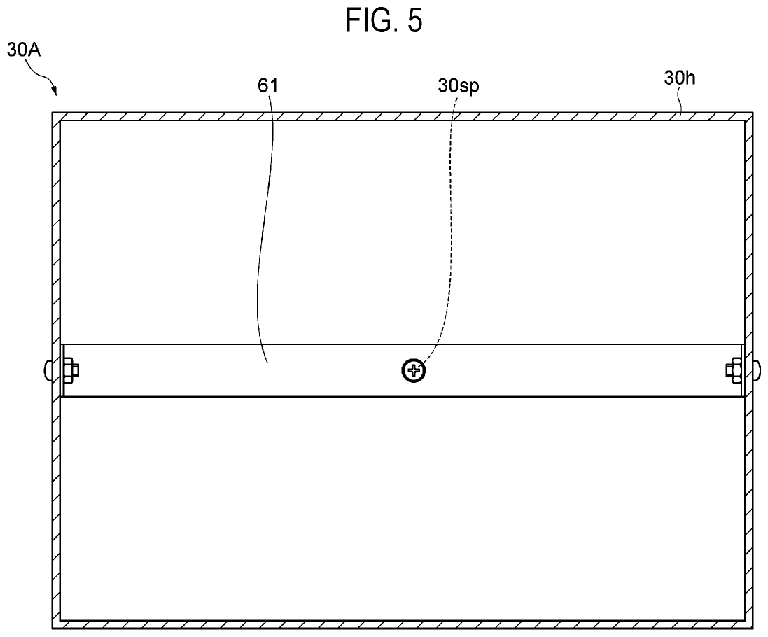

Reference will now be made to FIGS. 3 to 5 together with FIG. 1. FIG. 3 is a cross-sectional view showing the coupler according to one exemplary embodiment. FIG. 4 is a cross-sectional view taken along line IV-IV in FIG. 3. FIG. 5 is a cross-sectional view taken along line V-V in FIG. 3. FIG. 3 shows a structure of a coupler according to yet another exemplary embodiment in a vertical cross section taken along line III-III in FIG. 4. The coupler 30A shown in FIGS. 3 to 5 may be used as the coupler 30 of the plasma processing apparatus 1.

The coupler 30A includes a transmission line plate 313 made of a metal such as copper or the like and a dielectric member 312. The transmission line plate 313 extends horizontally along its longitudinal direction so as to connect the input portion 30i and the output portion 300 to each other. The dielectric member 312 is arranged between the transmission line plate 313 and the bottom portion of the housing 30h. The transmission line plate 313 constitutes the supply line 31, and constitutes a microstrip line together with the dielectric member 312 and the bottom portion of the housing 30h. The microstrip line has the above-mentioned constant characteristic impedance. The dielectric member 312 may not be arranged in a region between the transmission line plate 313 and the bottom portion of the housing 30h. The region between the transmission line plate 313 and the bottom portion of the housing 30h may be filled with, for example, air.

In the plasma processing apparatus 1 including the coupler 30A, the feeding portion 20p is arranged so as to have a distance r50, at which an impedance on a load side from the feeding portion 20p is 50Ω under desired plasma excitation conditions (center conditions) including the frequency of the radio-frequency power and the like, as a radial distance from the axis AX to the feeding portion 20p. In the coupler 30A, the variable reactance portion 36 includes a capacitor 51 as the capacitor 50 and includes an inductor 61 as the inductor 60.

The capacitor 51 has a plurality of capacitor elements 511. The capacitor elements 511 are a plurality of reactance elements. The capacitor elements 511 are connected to the supply line 40. Specifically, the capacitor elements 511 are connected to the supply line 31. In order to provide the capacitor elements 511, the capacitor 51 includes a capacitor plate 511p, a plurality of dielectric members 511d, and a plurality of capacitor patterns 511e of a printed circuit board 511b.

The capacitor plate 511p is made of a metal such as copper or the like, and extends horizontally above the transmission line plate 313. The transmission line plate 313, that is, the transmission line, includes a connection point 30s. The connection point 30s is located between the input portion 30i and the output portion 300. The capacitor plate 511p is connected to the connection point 30s via a metal pillar 30sp (connection member). The metal pillar 30sp extends upward from the connection point 30s.

The printed circuit board 511b extends in the horizontal direction above the capacitor plate 511p. The capacitor patterns 511e are formed on a back surface (lower surface) of the printed circuit board 511b so as to face the capacitor plate 511p. Each of the capacitor patterns 511e may have a substantially circular shape. The capacitor patterns 511e may be arranged along a longitudinal direction of the capacitor plate 511p. In the illustrated example, the capacitor patterns 511e are arranged to form two rows extending in a direction parallel to the longitudinal direction of the capacitor plate 511p. The printed circuit board 511b may provide a slit 511bh penetrating the printed circuit board 511b in a board thickness direction thereof. The slit 511bh may be formed between the two rows of the capacitor patterns 511e. The slit 511bh may reduce a parasitic capacitance of the printed circuit board 511b.

Each of the dielectric members 511d is held between the corresponding capacitor pattern among the capacitor patterns 511e and the capacitor plate 511p by using a screw. The dielectric members 511d may be made of polytetrafluoroethylene or the like, and may have a ring shape. An edge of each of the capacitor patterns 511e has a size slightly smaller than that of the dielectric members 511d so that the edge of each of the capacitor patterns 511e is located inside the edge of the corresponding dielectric member among the dielectric members 511d. This may suppress creeping discharges.

In the capacitor 51, each of the capacitor elements 511 includes a corresponding capacitor pattern among the plurality of capacitor patterns 511e and a corresponding dielectric member among the plurality of dielectric members 511d. The capacitor elements 511 share a capacitor plate 511p. The capacitor patterns 511e may have a same area. In this case, the capacitor elements 511 have a same electrostatic capacitance. In another embodiment, the capacitor elements 511 may have different capacitances.

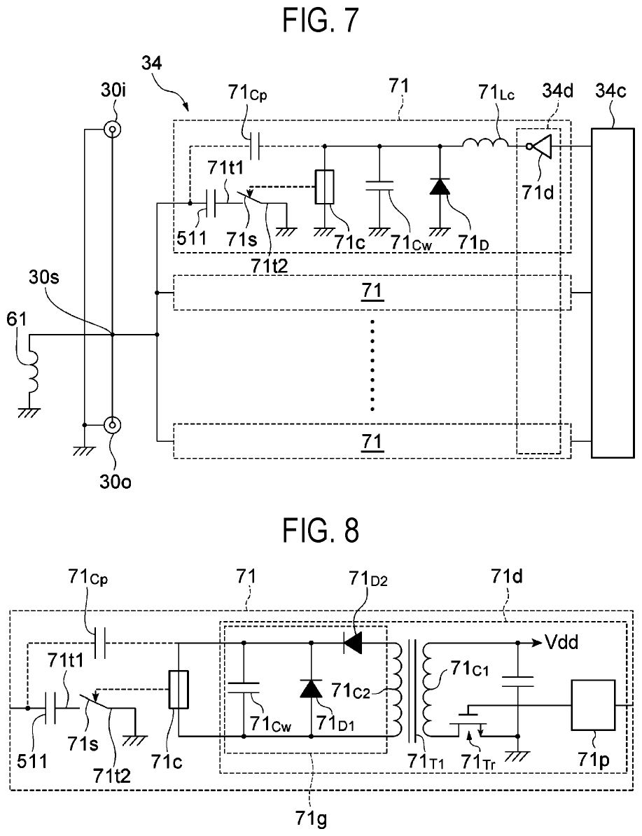

The matching circuit 34 of the coupler 30A further includes a plurality of relays 71. Each of the relays 71 includes a relay switch 71s and a relay coil 71c. The relay switch 71s includes a first contact 71t1 and a second contact 71t2 (see FIG. 7 and the like), and may switch disconnection and connection between the first contact 71t1 and the second contact 71t2 depending on a state (open or closed state) thereof. The relays 71 are provided on the printed circuit board 511b. The first contact of the relay switch of each of the relays 71 is connected to a corresponding capacitor pattern among the plurality of capacitor patterns 511e. The second contact of the relay switch of each of the relays 71 is connected to a ground pattern 511g provided on the back surface of the printed circuit board 511b. The ground pattern 511g is connected to the bottom portion of the housing 30h, that is, to the ground, via a plurality of metal pillars 51sp.

In the coupler 30A, the drive circuit 34d is connected to the relay coils 71c of the relays 71 via the connector 51cn. The drive circuit 34d is configured to apply a DC voltage signal for setting the state (open state or closed state) of the relay switch 71s of each of the relays 71 to the relay coil 71c of each of the relays 71. The control circuit 34c may communicate with the power supply controller 24c via a communication circuit 34t. The control circuit 34c is notified of an electrostatic capacitance setting value of the capacitor 51 for reducing the power level of the reflected wave from the power supply controller 24c via the communication circuit 34t. The control circuit 34c controls the drive circuit 34d to set the state of the relay switch 71s of each of the relays 71 in order to set the capacitance of the capacitor 51 to the notified setting value. In the coupler 30A, the capacitance of the capacitor 51 may be adjusted by adjusting the state of the relay switch 71s of each of the relays 71.

In the coupler 30A, the capacitor elements 511 are arranged in one or more rows. However, the capacitor elements 511 may be arranged in a circumferential direction around an axis extending vertically from the connection point 30s. The capacitor elements 511 may be arranged at equal intervals. Further, the relays 71 may be arranged in a circumferential direction radially outside the capacitor elements 511.

In the coupler 30A, the matching circuit 34 includes an inductor 61 as the inductor 60. The inductor 61 includes an inductor plate, which is a conductor plate made of a metal such as copper or the like. The inductor plate extends in the horizontal direction above the printed circuit board 511b. The inductor plate is connected to the connection point 30s via the metal pillar 30sp.

Plural pairs of holes 30th are formed in a pair of sidewalls of the housing 30h. The pairs of holes 30th are arranged along the vertical direction. Both ends of the inductor plate are fixed to the pair of sidewalls of the housing 30h using a pair of screws inserted into a pair of holes 30th selected from the pairs of holes 30th and a pair of nuts. With the coupler 30A, it is possible to change an electrical length between the inductor plate and the connection point 30s by changing the pair of holes 30th selected from the pairs of holes 30th. This makes it possible to change an inductance of the inductor 61.

An inductance L of the inductor 61 is set to satisfy ωL=1/(ωCh), where ω is a plasma excitation angular frequency, and Ch is a median value of a changeable range of the capacitance of the capacitor 51.

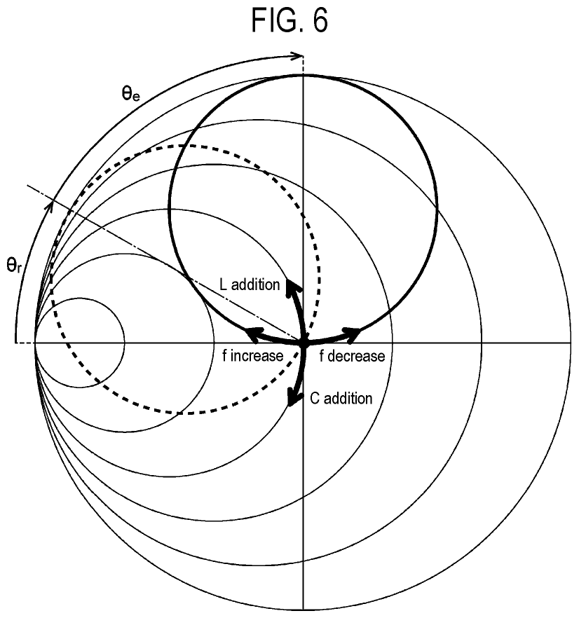

Hereinafter, reference is further made to FIG. 6. FIG. 6 is an admittance chart related to the coupler according to one exemplary embodiment. In FIG. 6, “f increase” and “f decrease” represent a direction of change in a load-side impedance of the connection point 30s and the corresponding reflection coefficient when the frequency of the radio-frequency power is increased or decreased. Further, in FIG. 6, “L addition” and “C addition” represent a direction of change in the load-side impedance of the connection point 30s and the corresponding reflection coefficient when the reactance of the variable reactance portion 36 is changed. Specifically, “L addition” represents a change in the load-side impedance of the connection point 30s and the reflection coefficient when the inductance of the variable reactance portion 36 is increased. Further, “C addition” represents a change in the load-side impedance of the connection point 30s and the reflection coefficient when the capacitance of the variable reactance portion 36 is increased.

In the plasma processing apparatus 1, a position of the connection point 30s may be set so as to satisfy an orthogonal condition. That is, the position of the connection point 30s may be determined so that a change in the reflection coefficient corresponding to the load-side impedance of the connection point 30s when the reactance of the variable reactance portion 36 is changed (see the arrow on the iso-conductance curve in FIG. 6) and a change in the reflection coefficient when the frequency of the radio-frequency power generated by the radio-frequency power supply 24 is changed (see the arrow on the thick solid line in FIG. 6) satisfy an orthogonal condition in a coordinate system having a real axis and an imaginary axis that are orthogonal to each other as shown in FIG. 6.

When the orthogonal condition is satisfied, it is possible to increase a range in which the impedance may be changed in the plasma processing apparatus 1. In addition, the load impedance change caused by the reactance change in the variable reactance portion 36 and the load impedance change caused by the frequency change of the radio-frequency power generated by the radio-frequency power supply 24 become highly independent from each other. Therefore, impedance matching becomes easy.

Hereinafter, specific conditions for satisfying the orthogonal condition will be described below with further reference to FIG. 6. When the orthogonal condition is satisfied, the load-side impedance of the connection point 30s is changed along the thick solid line in FIG. 6 when the frequency of the radio-frequency power generated by the radio-frequency power supply 24 is changed. Further, the impedance as seen from the feeding portion 20p to the load side when changing the frequency of the radio-frequency power generated by the radio-frequency power supply 24 is changed along the circle indicated by the broken line in FIG. 6. In order for an angle that a line extending from the center point (point indicating 50Ω) on the real axis through the center of the thick solid line circle in FIG. 6 makes with respect to the real axis to be 90 degrees, the position of the connection point 30s with respect to the feeding portion 20p needs to be set so as to provide an angle de which is a difference between an angle θᵣ that the one-dot chain line extending from the center point (point indicating 50Ω) on the real axis through the center of the broken line circle in FIG. 6 makes with respect to the real axis and 90 degrees.

In this regard, the angle θr is 4π×Lᵣ/λ_{gr}, and the angle θₑ is 4π×Lₑ/λ_{ge}. Lᵣ is the length along the radial direction between the feeding portion 20p and the upper end (first end 201) of the resonator 20. λ_{gr} is the wavelength of the electromagnetic waves in the waveguide 20w of the resonator 20 between the feeding portion 20p and the upper end (first end 201) of the resonator 20. Lₑ is the length between the feeding portion 20p and the connection point 30s. λge is the wavelength of the electromagnetic waves between the feeding portion 20p and the connection point 30s. When the sum of the angle θᵣ and the angle θₑ is (2n+1) times 90 degrees, the orthogonal condition is satisfied. Therefore, the orthogonal condition is satisfied when Formula (1) below is satisfied. Where, n is 0 or a positive integer.

$$[ Formula 1 ]$$

$$\frac{{L}_{e}}{{λ}_{ge}} + \frac{{L}_{r}}{{λ}_{gr}} ≅ \frac{2 n + 1}{8} \qquad ( 1 )$$

Reference will now be made to FIG. 7. FIG. 7 is a diagram showing a matching circuit according to one exemplary embodiment. A matching circuit 34 shown in FIG. 7 may be employed as the matching circuit 34 of the plasma processing apparatus 1. In the matching circuit 34 shown in FIG. 7, the drive circuit 34d includes a plurality of drive circuits 71d. The drive circuits 71d may be provided as elements of the relays 71, respectively.

In each of the relays 71, the drive circuit 71d is configured to apply the above-mentioned DC voltage signal to the relay coil 71c when the relay switch 71s is set to a closed state under the control of the control circuit 34c. The drive circuit 71d may include, for example, a buffer transistor. As shown in FIG. 7, a choke coil 71_{Lc} may be connected between the drive circuit 71d and one end of the relay coil 71c. This suppresses the radio-frequency current from flowing into the drive circuit 71d.

As shown in FIG. 7, in the matching circuit 34, each of the relays 71 includes a diode 71D and a capacitor 71_{Cw}. The diode 71D and the capacitor 71_{Cw} are connected in parallel to the relay coil 71c.

A cathode of the diode 71D is connected to one end (a positive end portion) of the relay coil 71c, and an anode of the diode 71D is connected to the ground. The diode 71D is configured to rectify the radio-frequency current flowing through a parasitic capacitance 71_{Cp} between the relay coil 71c and the corresponding capacitor element 511.

The capacitor 71_{Cw} is configured to generate a DC voltage to be applied to the relay coil 71c in response to a current generated by rectifying the radio-frequency current with the diode 71D. The relay switch 71s has a characteristic of transitioning from a closed state to an open state when the DC voltage applied to the relay coil 71c drops to a voltage level equal to or lower than a threshold voltage level. The capacitance (electrostatic capacitance) of the capacitor 71_{Cw} is set so that the DC voltage generated by the capacitor 71_{Cw} has a voltage level higher than the threshold voltage level of the relay switch 71s.

In each of the relays 71, the radio-frequency voltage applied to the capacitor element 511 is divided by the parasitic capacitance 71_{Cp} and the capacitor 71_{Cw}, and is rectified by the diode 71D to generate a DC voltage across the capacitor 71_{Cw}. A voltage level of the DC voltage generated across the capacitor 71_{Cw} is higher than the above-mentioned threshold voltage level. This suppresses the state of the relay switch 71s from being unintentionally changed from the closed state to the open state due to noise or the like.

Reference will now be made to FIG. 8. FIG. 8 is a diagram showing a relay according to another exemplary embodiment. A relay 71 shown in FIG. 8 may be employed as each of the relays 71 of the matching circuit 34. The relay 71 shown in FIG. 8 will be described below in terms of differences from the relay 71 shown in FIG. 7.

In the relay 71 shown in FIG. 8, the relay coil 71c is floating from the ground with respect to radio frequencies. The drive circuit 71d of the relay 71 includes a transformer 71_{T1} and a DC voltage generation circuit 71g. The drive circuit 71d further includes a transistor 71_{Tr} and a pulse generator 71p.

In the relay 71 shown in FIG. 8, the transformer 71_{T1} is provided to prevent radio-frequency noise from being transmitted to the control circuit 34c and the drive circuit 34d. The transformer 71_{T1} may have a magnetic core made of a ferrite material. A DC power supply is connected to one end of the primary coil 71_{C1} of the transformer 71_{T1}, and a voltage Vdd is applied to the primary coil 71_{C1}. A transistor 71_{Tr} is connected between the other end of the primary coil 71_{C1} and the ground. The pulse generator 71p generates a radio-frequency pulse and supplies the same to a control terminal of the transistor 71_{Tr}. A frequency of the radio-frequency pulse is, for example, 160 kHz. When the radio-frequency pulse is applied to the transistor 71_{Tr}, a pulse current is generated in the secondary coil 71_{C2} of the transformer 71_{T1}.

The DC voltage generation circuit 71g is connected between the relay coil 71c and the secondary coil 71_{C2} of the transformer 71_{T1}. The DC voltage generation circuit 71g includes a capacitor 71_{Cw}, a first diode 71_{D1}, and a second diode 71_{D2}. One end of the secondary coil 71_{C2} is connected to one end of the relay coil 71c via the second diode 71_{D2}. An anode of the second diode 71_{D2} is connected to one end of the secondary coil 71_{C2}, and a cathode of the second diode 71_{D2} is connected to one end of the relay coil 71c.

The capacitor 71_{Cw} and the first diode 71_{D1} are connected in parallel between the relay coil 71c and the secondary coil 71_{C2}. A cathode of the first diode 71_{D1} is connected to one end of the relay coil 71c and the cathode of the second diode 71_{D2}. An anode of the first diode 71_{D1} is connected to the other end of the relay coil 71c and the other end of the secondary coil 71_{C2}.

The pulse current generated in the secondary coil 71_{C2} charges the capacitor 71_{Cw} via the second diode 71_{D2}. When the radio-frequency pulse is in an OFF state, a return current generated by an inductance component of the relay coil 71c flows through the first diode 71_{D1}. Thus, a DC voltage is generated in the capacitor 71_{Cw}, and a DC voltage signal is applied to the relay coil 71c. As a result, the relay switch 71s is set to the closed state.

In the relay 71 shown in FIG. 8, the radio-frequency voltage applied to the capacitor element 511 is divided by the parasitic capacitance 71_{Cp} and the capacitor 71_{Cw}, and a DC voltage is generated across the capacitor 71_{Cw}. A voltage level of the DC voltage generated across the capacitor 71_{Cw} is higher than the above-mentioned threshold voltage level. This suppresses the state of the relay switch 71s from being unintentionally changed from the closed state to the open state due to noise or the like.

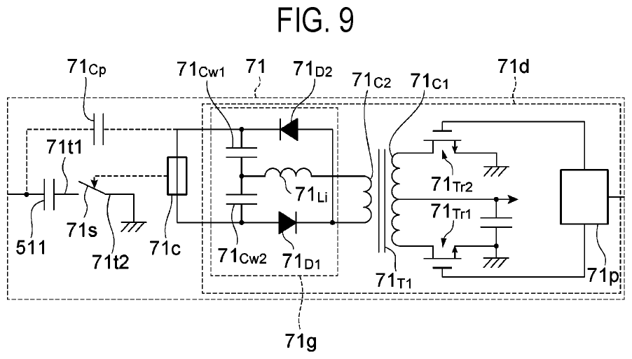

Reference will now be made to FIG. 9. FIG. 9 is a diagram showing a relay according to yet another exemplary embodiment. A relay 71 shown in FIG. 9 may be employed as each of the relays 71 of the matching circuit 34. The relay 71 shown in FIG. 9 will be described below in terms of differences from the relay 71 shown in FIG. 7.

In the relay shown in FIG. 9, the relay coil 71c is floating from the ground with respect to radio frequencies. The drive circuit 71d of the relay 71 includes a transformer 71_{T1} and a DC voltage generation circuit 71g. The drive circuit 71d further includes a first transistor 71_{Tr1}, a second transistor 71_{Tr2}, and a pulse generator 71p.

In the relay 71 shown in FIG. 9, the transformer 711 is provided to prevent radio-frequency noise from being transmitted to the control circuit 34c and the drive circuit 34d. The transformer 711 may have a magnetic core made of a ferrite material. A second transistor 71_{Tr2} is connected between one end of the primary coil 71_{C1} of the transformer 71_{T1} and the ground. A first transistor 71_{Tr1} is connected between the other end of the primary coil 71_{C1} and the ground. The pulse generator 71p supplies a radio-frequency pulse for switching the first transistor 71_{Tr1} and the second transistor 71_{Tr2} in opposite phases to control terminals of the first transistor 71_{Tr1} and the second transistor 71_{Tr2}, respectively. A frequency of the radio-frequency pulse is, for example, 160 kHz. When the radio-frequency pulse is applied to the control terminals of the first transistor 71_{Tr1} and the second transistor 71_{Tr2}, a pulse current is generated in the secondary coil 71_{C2} of the transformer 71_{T1}.

In the relay 71 shown in FIG. 9, the DC voltage generation circuit 71g is connected between the relay coil 71c and the secondary coil 71_{C2}. The DC voltage generation circuit 71g includes a first capacitor 71_{Cw1}, a second capacitor 71_{Cw2}, a first diode 71_{D1}, and a second diode 71_{D2}. One end of the first capacitor 71_{Cw1} is connected to one end of the relay coil 71c. One end of the second capacitor 71_{Cw2} is connected to the other end of the first capacitor 71_{Cw1} and one end of the secondary coil 71_{C2}. An inductor 71_{Li} may be connected between each of the other end of the first capacitor 71_{Cw1} and one end of the second capacitor 71_{Cw2} and one end of the secondary coil 71_{C2}. The inductor 71_{Li} is configured to block or attenuate the radio-frequency current flowing through the parasitic capacitance 71_{Cp} to suppress magnetic saturation of the transformer 71_{T1}.

An anode of the first diode 71_{D1} is connected to the other end of the relay coil 71c and the other end of the second capacitor 71_{Cw2}. A cathode of the first diode 71_{D1} is connected to the other end of the secondary coil 71_{C2}. An anode of the second diode 71_{D2} is connected to the cathode of the first diode 71_{D1} and the other end of the secondary coil 71_{C2}. A cathode of the second diode 71_{D2} is connected to one end of the relay coil 71c and one end of the first capacitor 71_{Cw1}.

The pulse current generated in the secondary coil 71_{C2} alternately passes through the first diode 71_{D1} and the second diode 71_{D2} to charge the first capacitor 71_{Cw1} and the second capacitor 71_{Cw2}. Thus, a DC voltage is generated across the series connection of the first capacitor 71_{Cw1} and the second capacitor 71_{Cw2}, and a DC voltage signal is applied to the relay coil 71c. As a result, the relay switch 71s is set to the closed state.

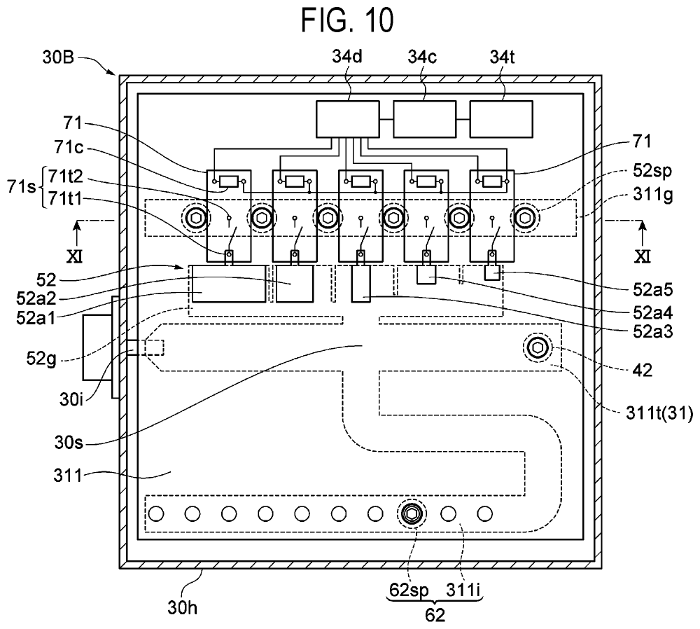

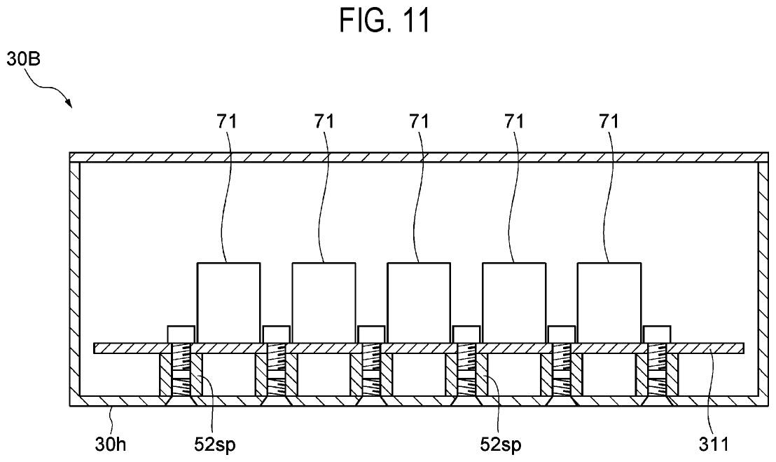

In the relay 71 shown in FIG. 9, the radio-frequency voltage applied to the capacitor element 511 is divided by the parasitic capacitance 71_{Cp} and the series connection of the first capacitor 71_{Cw1} and the second capacitor 71_{Cw2}. As a result, a DC voltage is generated between both ends of the series connection of the first capacitor 71_{Cw1} and the second capacitor 71_{Cw2}. A voltage level of the DC voltage generated between both ends of the series connection of the first capacitor 71_{Cw1} and the second capacitor 71_{Cw2} is higher than the above-mentioned threshold voltage level. This suppresses the state of the relay switch 71s from being unintentionally changed from the closed state to the open state due to noise or the like. Hereinafter, a coupler according to another exemplary embodiment will be described with reference to FIGS. 10 and 11. FIG. 10 is a cross-sectional view showing the coupler according to another exemplary embodiment. FIG. 11 is a cross-sectional view taken along line XI-XI in FIG. 10. FIG. 11 shows a structure in a vertical cross section of the coupler according to the exemplary embodiment. A coupler 30B shown in FIGS. 10 and 11 may be used as the coupler 30 of the plasma processing apparatus 1. Hereinafter, the coupler 30B will be described in terms of differences from the coupler 30A.

The coupler 30B includes a printed circuit board 311. The printed circuit board 311 may be made of a material having a relatively small dielectric tangent. For example, the printed circuit board 311 may be made of a glass epoxy material containing an inorganic material dispersed therein. The printed circuit board 311 is provided inside the housing 30h.

The coupler 30B includes a transmission line pattern 311t and an inductor pattern 311i. The transmission line pattern 311t and the inductor pattern 311i are formed on a back surface of the printed circuit board 311. The transmission line pattern 311t extends in its longitudinal direction from the input portion 30i to a connection point to the supply line 42. In the coupler 30B, the transmission line pattern 311t and the bottom portion of the housing 30h form the supply line 31, that is, the above-mentioned transmission line. This transmission line also has the above-mentioned constant characteristic impedance.

The coupler 30B includes a capacitor 52 as the capacitor 50 of the variable reactance portion 36. The capacitor 52 is formed of a plurality of capacitor elements. The number M of the capacitor elements in the capacitor 52 may be any number equal to or greater than two.

The capacitor 52 includes a capacitor pattern 52g and capacitor patterns 52a1 to 52a5. The capacitor pattern 52g is formed on the back surface of the printed circuit board 311. The capacitor pattern 52g is connected to the connection point 30s. The capacitor patterns 52al to 52a5 are formed on an upper surface of the printed circuit board 311 so as to face the capacitor pattern 52g with the printed circuit board 311 (dielectric member) interposed therebetween.

Each of the capacitor patterns 52a1 to 52a5 forms a plurality of capacitor elements together with the printed circuit board 311 and the capacitor pattern 52g. That is, the capacitor elements include the capacitor patterns 52al to 52a5 as first electrodes thereof. The capacitor elements include the capacitor pattern 52g as a second electrode common to the respective capacitor elements. In addition, the capacitor elements include the printed circuit board 311 as a dielectric member common to the respective capacitor elements.

In the capacitor 52, the capacitor pattern 52g may provide a plurality of slits, each of which extends between two adjacent capacitor elements so as to suppress interference between the capacitor elements.

The capacitor patterns 52a1 to 52a5 may have different areas so that the capacitor elements have different capacitances. The capacitance, that is, electrostatic capacitance, of each of the capacitor elements of the capacitor 52 may satisfy Cₘ=0.5×Cₘ₋₁, where Cₘ is the capacitance of an m-th capacitor element among a first to M-th capacitor elements, which are a plurality of capacitor elements. The electrostatic capacitances of the capacitor elements are, for example, 12.8 pF, 6.4 pF, 3.2 pF, 1.6 pF, and 0.8 pF, respectively.

In the coupler 30B, the matching circuit 34 further includes a plurality of relays 71. In the coupler 30B, the relays 71 have the configuration shown in any one of FIG. 7 to FIG. 9 in order to switch disconnection and connection between each of the capacitor elements of the coupler 30B and the ground. The relays 71 may be mounted on the upper surface of the printed circuit board 311. Each of the relays 71 includes a relay switch 71s and a relay coil 71c. The relay switch 71s includes a first contact 71t1 and a second contact 71t2, and may switch disconnection and connection between the first contact 71t1 and the second contact 71t2 depending on the state (open or closed state) thereof. The first contact 71t1 of the relay switch 71s of each of the relays 71 is connected to a corresponding one of the capacitor patterns 52al to 52a5. The second contact 71t2 of each of the relay switches 71s of the relays 71 is connected to a ground pattern 311g provided on the back surface of the printed circuit board 311. The ground pattern 311g is connected to the bottom portion of the housing 30h, that is, to the ground, via a plurality of short-circuit members 52sp (for example, metal pillars).

In the coupler 30B, the drive circuit 34d is configured to apply a DC voltage signal for setting the state (open or closed state) of the relay switch 71s of each of the relays 71 to the relay coil 71c of each of the relays 71. The control circuit 34c is capable of communicating with the power supply controller 24c via the communication circuit 34t. The control circuit 34c is notified of a set value of the capacitance of the capacitor 52 for reducing the power level of the reflected wave from the power supply controller 24c via the communication circuit 34t. The control circuit 34c controls the drive circuit 34d to set the state of the relay switch 71s of each of the relays 71 in order to set the capacitance of the capacitor 52 to the notified set value.

In the coupler 30B, the capacitance of the capacitor 52 may be adjusted by setting the state of the relay switch 71s of each of the relays 71. In one embodiment, the capacitance of the capacitor 52 may be changed in 32 binary steps.

In the coupler 30B, the inductor pattern 311i forms an inductor 62 as the inductor 60 of the variable reactance portion 36. The inductor pattern 311i is configured to be able to change a length (electrical length) from one end thereof to a portion short-circuited to the ground. In the printed circuit board 311, a plurality of holes 311h penetrating the printed circuit board 311 in a board thickness direction are formed so as to be arranged side by side between one end and the other end of the inductor pattern 311i. The inductor pattern 311i is short-circuited to the ground by threadedly fitting a screw inserted into a selected hole of the plurality of holes 311h into a thread hole of a short-circuiting member 62sp (for example, a metal pillar) sandwiched between the inductor pattern 311i and the bottom portion of the housing 30h. The inductor 62 may change the length from one end to the portion short-circuited to the ground in the inductor pattern 311i by changing the hole selected from the plurality of holes 311h. This allows the inductor 62 to change the inductance thereof.

The inductance L of the inductor 62 is set to satisfy ωL=1/(ωCh), where ω is a plasma excitation angular frequency, and Ch is a median value of the variable range of the capacitance of the capacitor 52.

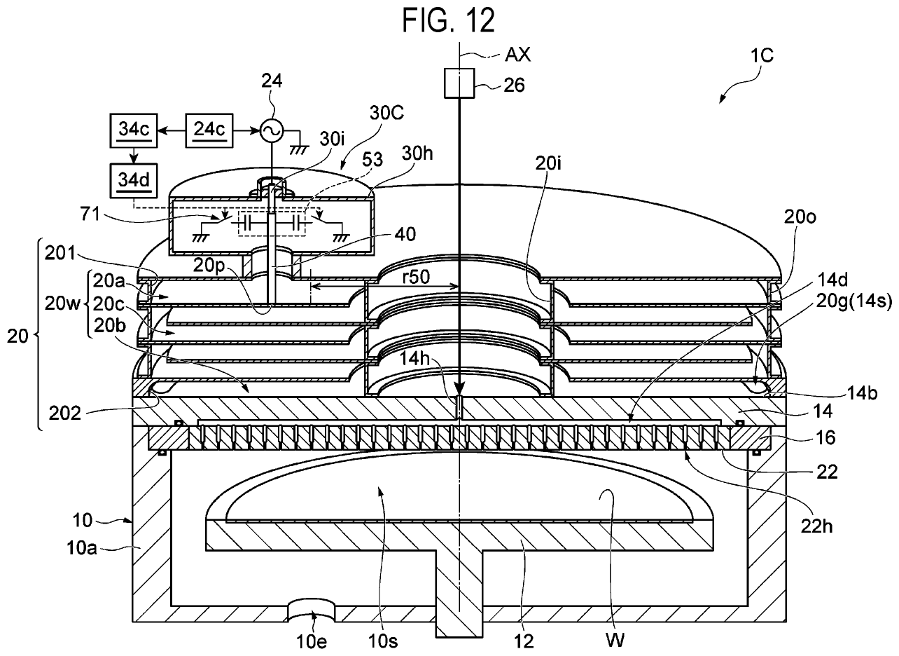

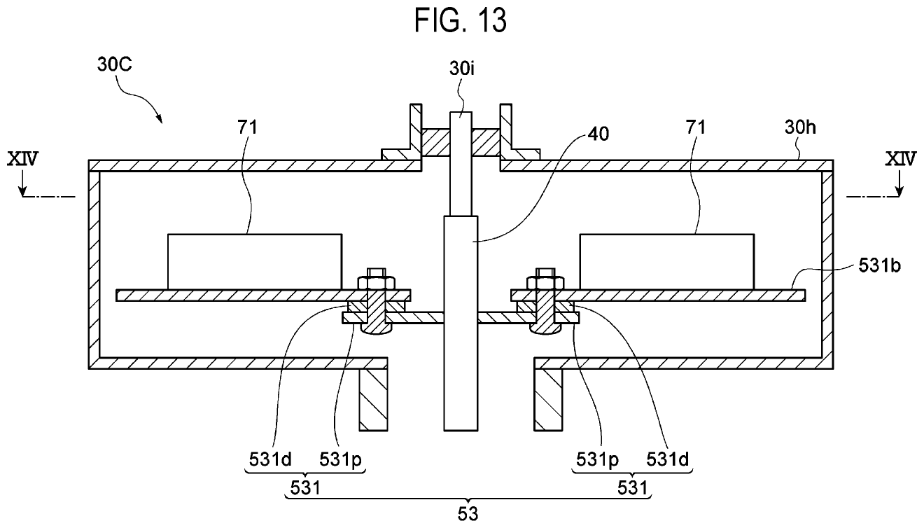

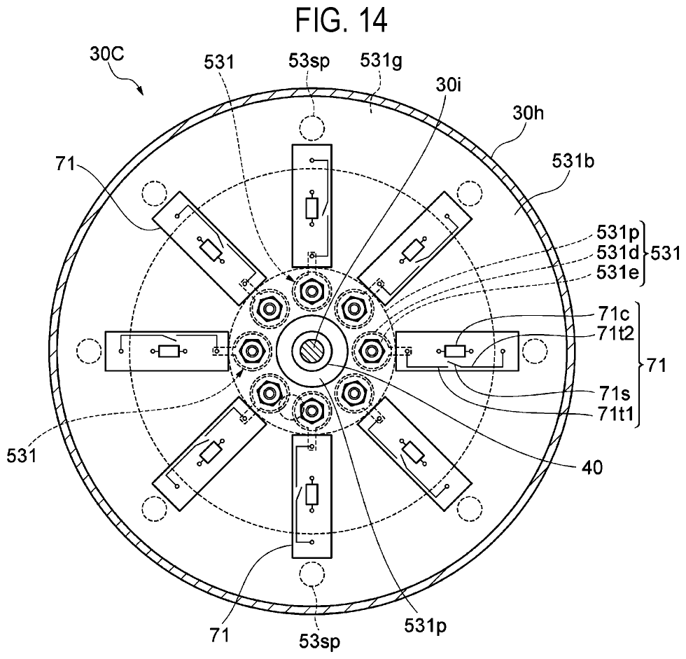

Still another exemplary embodiment will now be described with reference to FIGS. 12 to 14. FIG. 12 is a diagram showing a plasma processing apparatus according to another exemplary embodiment. FIG. 13 is a cross-sectional view showing a coupler according to yet another exemplary embodiment. FIG. 14 is a cross-sectional view taken along line XIV-XIV in FIG. 13. FIG. 13 shows a structure in a vertical cross section of the coupler according to still another exemplary embodiment. Hereinafter, a plasma processing apparatus 1C shown in FIG. 12 will be described in terms of differences from the plasma processing apparatus 1. In addition, the coupler 30C of the plasma processing apparatus 1C will be described in terms of differences from the coupler 30A.

In the plasma processing apparatus 1C, the supply line 40 is configured as a metallic coupling rod. The supply line 40 extends upward from the feeding portion 20p to the input portion 30i. In the plasma processing apparatus 1C, the feeding portion 20p may be provided at a position outside a radial position where the load-side impedance from the feeding portion 20p is 50Ω under desired plasma excitation conditions (center conditions) including the frequency of the radio-frequency power and the like. That is, the radial distance from the axis AX to the feeding portion 20p may be longer than the above-mentioned r50.

In the coupler 30C, the matching circuit 34 may not include the inductor 60. In the coupler 30C, the matching circuit 34 includes a capacitor 53 as the capacitor 50. The capacitor 53 includes a plurality of capacitor elements 531. The capacitor elements 531 are arranged in a circumferential direction around the supply line 40, that is, the central axis of the coupling rod. The capacitor elements 531 may be arranged at equal intervals. In addition, in the matching circuit 34 of the coupler 30C, each of the relays 71 is arranged radially outward with respect to a corresponding capacitor element among the plurality of capacitor elements 531. That is, the relays 71 are also arranged in a circumferential direction around the central axis of the coupling rod. In addition, in the coupler 30C, the relays 71 have the configuration shown in any one of FIG. 7 to FIG. 9. In the matching circuit 34 of the coupler 30C, the relays 71 are configured to switch disconnection and connection between each of the capacitor elements 531 and the ground.

The coupler 30C further includes a printed circuit board 531b. The printed circuit board 531b is provided inside the housing 30h and extends along the horizontal direction. The printed circuit board 531b has a substantially circular shape and is open at its center. The supply line 40 extends through an opening of the printed circuit board 531b. The printed circuit board 531b provides a plurality of capacitor patterns 531e and a ground pattern 531g on its lower surface. The capacitor patterns 531e and the ground pattern 531g are formed of a metal such as copper or the like. The capacitor patterns 531e have a substantially circular shape and are arranged along the circumferential direction around the supply line 40, that is, the central axis of the coupling rod. The ground pattern 531g extends radially outward from the capacitor patterns 531e. The ground pattern 531g may have a ring shape. The ground pattern 531g is connected to the bottom portion of the housing 30h, that is, to the ground, via a plurality of metal pillars 53sp.

In the coupler 30C, the matching circuit 34 further includes a capacitor plate 531p made of a metal such as copper or the like. The capacitor plate 531p extends below the printed circuit board 531b so as to face the capacitor patterns 531e. The capacitor plate 531p may have a substantially ring shape. An inner edge of the capacitor plate 531p is connected to the supply line 40.

Further, in the coupler 30C, the matching circuit 34 includes a plurality of dielectric members 531d. The dielectric members 531d are formed of, for example, polytetrafluoroethylene. The dielectric members 531d may have a ring shape. Each of the dielectric members 531d is sandwiched between a corresponding capacitor pattern among the plurality of capacitor patterns 531e and the capacitor plate 531p. Each of the capacitor elements 531 described above is composed of one of the capacitor patterns 531e, the capacitor plate 531p, and a dielectric member among the plurality of dielectric members 531d arranged therebetween.

The capacitor patterns 531e may have a same area. In this case, the capacitor elements 531 have a same capacitance (electrostatic capacitance). An edge of each of the capacitor patterns 531e may have a size slightly smaller than that of the dielectric members 531d so as to be located inward of the edge of the corresponding dielectric member among the dielectric members 531d. This may suppress creeping discharges.

In the matching circuit 34 of the coupler 30C, each of the relays 71 has a configuration similar to that of the relays 71 in the coupler 30A. In the matching circuit 34 of the coupler 30C, the first contact 71t1 of the relay switch 71s of each of the relays 71 is connected to a corresponding one of the capacitor patterns 531e. In addition, the second contact 71t2 of the relay switch 71s of each of the relays 71 is connected to the ground pattern 531g.

In the coupler 30C, similarly to the coupler 30A, the drive circuit 34d is configured to apply a DC voltage signal for setting the state (open state or closed state) of the relay switch 71s of each of the relays 71 to the relay coil 71c of each of the relays 71. The control circuit 34c is capable of communicating with the power supply controller 24c via the communication circuit 34t. The control circuit 34c is notified of a set value of the capacitance of the capacitor 53 for reducing the power level of the reflected wave from the power supply controller 24c via the communication circuit 34t. The control circuit 34c controls the drive circuit 34d to set the state of the relay switch 71s of each of the relays 71 in order to set the capacitance of the capacitor 53 to the notified set value.

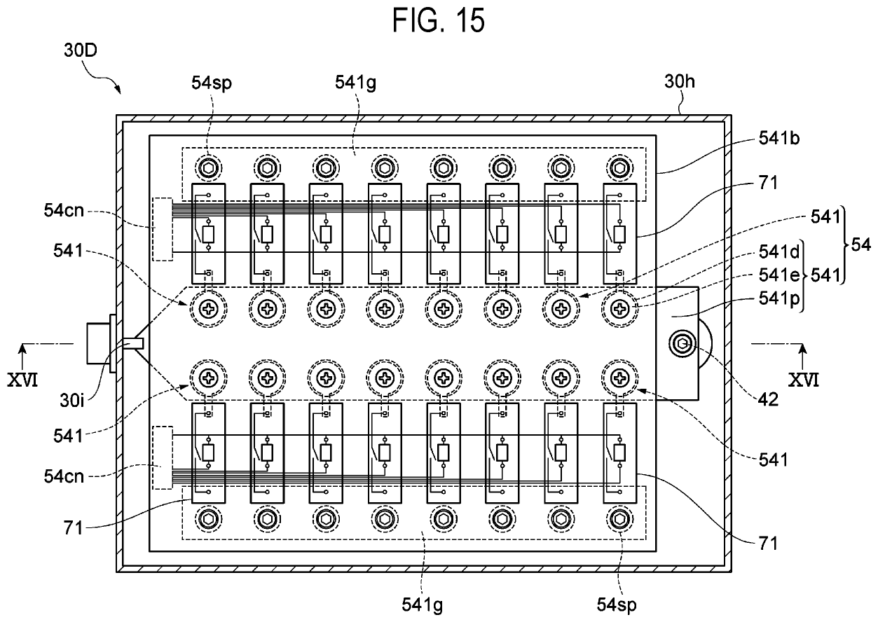

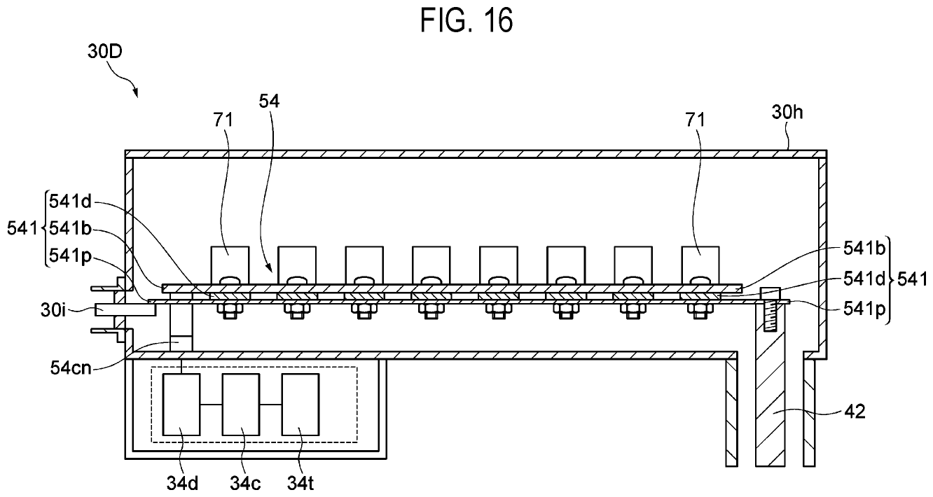

A coupler according to yet another exemplary embodiment will now be described with reference to FIGS. 15 and 16. FIG. 15 is a cross-sectional view showing the coupler according to yet another exemplary embodiment. FIG. 16 is a cross-sectional view taken along line XVI-XVI in FIG. 15. FIG. 16 shows a structure in a vertical cross section of the coupler according to still another exemplary embodiment. A coupler 50D shown in FIGS. 15 and 16 may be used in place of the coupler 30C of the plasma processing apparatus 1C. Hereinafter, the coupler 30D will be described in terms of differences from the coupler 30C.

In the coupler 30D, the supply line 42 is configured as a coaxial line or a coupling rod extending upward from the feeding portion 20p. In the coupler 30D, the matching circuit 34 does not need to include the inductor 60. In the coupler 30D, the matching circuit 34 includes a capacitor 54 as the capacitor 50. The capacitor 54 includes a plurality of capacitor elements 541. The plurality of capacitor elements 541 are arranged in one or more rows. In the illustrated example, the plurality of capacitor elements 541 are arranged in two rows.

The matching circuit 34 of the coupler 30D includes a printed circuit board 541b, a capacitor plate 541p, and a plurality of dielectric members 514d. The printed circuit board 541b, the capacitor plate 541p, and the plurality of dielectric members 514d are provided inside a housing 30h.

The printed circuit board 541b is provided inside the housing 30h and extends along the horizontal direction. The printed circuit board 541b may have a substantially rectangular shape. The printed circuit board 541b provides a plurality of capacitor patterns 541e and a ground pattern 541g on its lower surface. The plurality of capacitor patterns 541e and the ground pattern 541g are formed of a metal such as copper or the like. The plurality of capacitor patterns 541e have a substantially circular shape. The plurality of capacitor patterns 541e are arranged in one or more rows (two rows in the illustrated example) as described above. The ground pattern 541g is connected to the bottom portion of the housing 30h, that is, to the ground, via a plurality of metal pillars 54sp.

The capacitor plate 541p extends horizontally below the printed circuit board 541b so as to face the plurality of capacitor patterns 541e. The capacitor plate 541p may have a rectangular shape. The capacitor plate 541p constitutes the supply line 31, and constitutes the supply line 40 together with the supply line 42. The capacitor plate 541p extends along its longitudinal direction from the input portion 30i to the connection portion with the supply line 42.

Each of the plurality of dielectric members 541d is held between a corresponding capacitor pattern among the plurality of capacitor patterns 541e and the capacitor plate 541p by a screw. The dielectric members 541d may be made of polytetrafluoroethylene or the like and may have a ring shape. Each of the plurality of capacitor elements 541 described above is composed of one of the plurality of capacitor patterns 541e, the capacitor plate 541p, and the dielectric member among the plurality of dielectric members 541d arranged therebetween.

The plurality of capacitor patterns 541e may have a same area. In this case, the plurality of capacitor elements 541 have a same capacitance (electrostatic capacitance). An edge of each of the capacitor patterns 541e may have a size slightly smaller than that of the dielectric members 541d so that the edge of each of the plurality of capacitor patterns 541e is located inward of the edge of the corresponding dielectric member among the plurality of dielectric members 541d. This may suppress creeping discharges.

In the matching circuit 34 of the coupler 30D, each of the relays 71 has the same configuration as the above-mentioned relays 71 in the coupler 30A. That is, in the coupler 30D, the relays 71 also have the configuration shown in any one of FIGS. 7 to 9 in order to switch connection and disconnection between each of the capacitor elements 541 and the ground. In the matching circuit 34 of the coupler 30D, the first contact 71t1 of the relay switch 71s of each of the relays 71 is connected to a corresponding capacitor pattern among the plurality of capacitor patterns 541e. In addition, the second contact 71t2 of the relay switch 71s of each of the plurality of relays 71 is connected to the ground pattern 541g.

In the coupler 30D, the drive circuit 34d is connected to the relay coil 71c of each of the plurality of relays 71 via the connector 54cn. The drive circuit 34d is configured to apply a DC voltage signal to the relay coil 71c of each of the plurality of relays 71 to set the state (open or closed state) of the relay switch 71s of each of the plurality of relays 71. The control circuit 34c may communicate with the power supply controller 24c via the communication circuit 34t. The control circuit 34c is notified of a capacitance setting value of the capacitor 54 for reducing the power level of the reflected wave from the power supply controller 24c via the communication circuit 34t. The control circuit 34c controls the drive circuit 34d to set the state of the relay switch 71s of each of the plurality of relays 71 in order to set the capacitance of the capacitor 54 to the notified setting value.

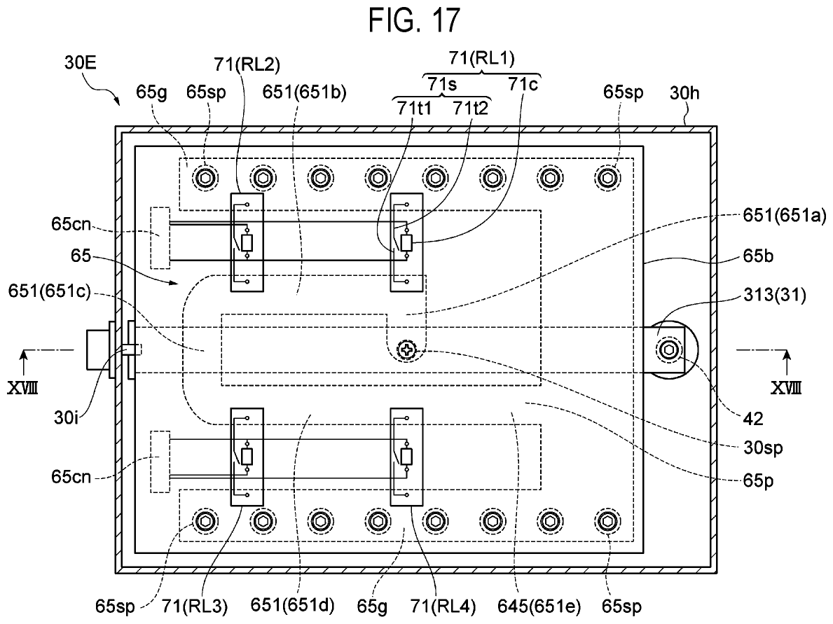

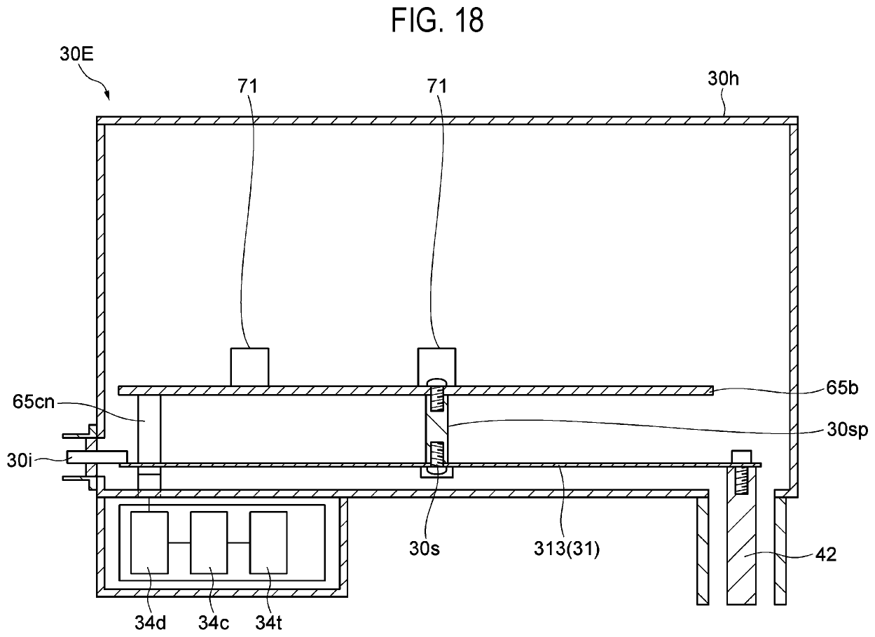

A plasma processing apparatus according to yet another exemplary embodiment will now be described. In the plasma processing apparatus according to yet another exemplary embodiment, the feeding portion 20p may be provided at a position inward of a radial position where the load-side impedance from the feeding portion 20p is 50Ω. That is, a radial distance from the axis AX to the feeding portion 20p may be shorter than the above-mentioned r50. In this case, in the variable reactance portion of the coupler of the plasma processing apparatus, only the inductor 60 may have a variable reactance. The coupler in which only the inductor 60 has a variable reactance may be, for example, the coupler shown in FIGS. 17 and 18. In this case, other configurations of the plasma processing apparatus are the same as the corresponding configurations of the plasma processing apparatus 1.

Hereinafter, reference will be made to FIGS. 17 and 18. FIG. 17 is a cross-sectional view showing a coupler according to yet another exemplary embodiment. FIG. 18 is a cross-sectional view taken along line XVIII-XVIII in FIG. 17. FIG. 18 shows a structure in a vertical cross section of the coupler according to still another exemplary embodiment. A coupler 30E shown in FIGS. 17 and 18 will now be described in terms of differences from the coupler 30A.

The coupler 30E includes a transmission line plate 313 made of a metal such as copper or the like. The transmission line plate 313 extends horizontally along its longitudinal direction to connect the input portion 30i and the output portion 300 to each other. The transmission line plate 313, together with the bottom portion of the housing 30h, constitutes the supply line 31, and constitutes a microstrip line. The microstrip line has the constant characteristic impedance described above.

In the coupler 30E, the matching circuit 34 includes an inductor 65 as the inductor 60. The inductor 65 includes an inductor pattern 65p. The inductor pattern 65p is formed on the back surface of the printed circuit board 65b. The printed circuit board 65b extends in the horizontal direction above the transmission line plate 313. One end of the inductor pattern 65p may be arranged at the center of the inductor pattern 65p or the center of the printed circuit board 65b. One end of the inductor pattern 65p is connected to the connection point 30s of the transmission line plate 313 via a metal pillar 30sp (connection member). The other end of the inductor pattern 65p is connected to a ground pattern 65g formed on the back surface of the printed circuit board 65b. The ground pattern 65g is connected to the bottom portion of the housing 30h via a plurality of metal pillars 65sp.

In the coupler 30E, the matching circuit 34 further includes a plurality of relays 71. The plurality of relays 71 are provided on the printed circuit board 65b. Each of the plurality of relays 71 in the coupler 30E has the same configuration as that of the relays 71 in the coupler 30A described above. That is, the plurality of relays 71 in the coupler 30E also have a configuration shown in any one of FIGS. 7 to 9 in order to switch connection and disconnection between each of the plurality of inductor elements 651 (described later) and the ground.

A first contact 71t1 of each of the plurality of relays 71 is connected to a different position of the inductor pattern 65p between one end and the other end of the inductor pattern 65p. A second contact 71t2 of each of the plurality of relays 71 is connected to the ground pattern 65g. The plurality of relays 71 divide the inductor patterns 65p into a plurality of inductor elements 651. The plurality of inductor elements 651 are a plurality of reactance elements. In the illustrated example, the plurality of relays 71 include four relays RL1 to RL4. In this example, the inductor pattern 65p is divided into five inductor elements 651a to 651e between one end and the other end of the inductor pattern 65p.

In the matching circuit 34 of the coupler 30E, the drive circuit 34d is connected to the relay coil 71c of each of the plurality of relays 71 via the connector 65cn. The drive circuit 34d is configured to apply a DC voltage signal for setting the state (open state or closed state) of the relay switch 71s of each of the plurality of relays 71 to the relay coil 71c of each of the plurality of relays 71. The control circuit 34c may communicate with the power supply controller 24c via the communication circuit 34t. The control circuit 34c is notified of a set value of the inductance of the inductor 65 for reducing the power level of the reflected wave from the power supply controller 24c via the communication circuit 34t. The control circuit 34c controls the drive circuit 34d to set the state of the relay switch 71s of each of the plurality of relays 71 in order to set the inductance of the inductor 65 to the notified set value. In the coupler 30E, the inductance of the inductor 65 may be adjusted by setting the state of the relay switch 71s of each of the plurality of relays 71.

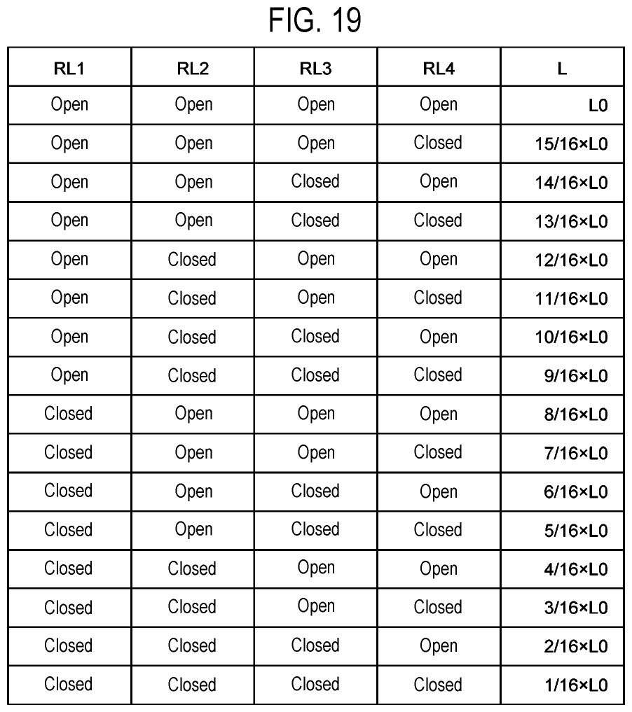

FIG. 19 is a table showing a relationship between the inductance and the state (open or closed state) of the relay switch of each of the plurality of relays in the coupler according to yet another exemplary embodiment. The table in FIG. 19 shows the relationship between the state of the relay switch 71s of each of the relays RL1 to RL4 and the inductance of the inductor 65. The inductance L of the inductor 65 is L0 when the relay switch 71s of each of the relays RL1 to RL4 is in the open state. When the relay switch 71s of each of the relays RL1 to RL4 is in a closed state, the inductor 65 provides an inductance. Thus, as shown in the table of FIG. 19, by adjusting the state of the relay switch 71s of each of the relays RL1 to RL4, the inductor 65 may change its inductance in 16 steps with the same inductance change amount.

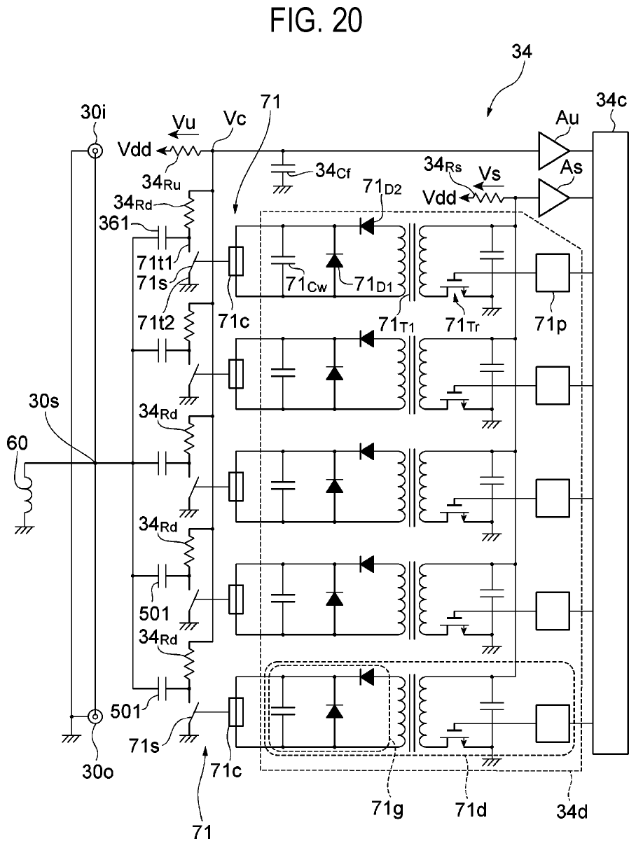

Hereinafter, a configuration for detecting a failure in a plurality of relays that may be employed in the couplers according to various exemplary embodiments will be described with reference to FIG. 20. FIG. 20 is a diagram showing an example of the configuration for detecting a failure in the plurality of relays that may be employed in couplers according to various exemplary embodiments.

As shown in FIG. 20, in various exemplary embodiments, the variable reactance portion 36 includes a plurality of reactance elements 361. The plurality of reactance elements 361 are the above-mentioned capacitor elements and/or inductor elements. Such a failure detection configuration shown in FIG. 20 is applied to the plurality of relays 71 for switching disconnection and connection between the plurality of reactance elements 361 and the ground. In the example of FIG. 20, a plurality of capacitor elements 501 are shown as the plurality of reactance elements 361. In another embodiment, the failure detection configuration of the plurality of relays 71 may be similarly applied to the plurality of inductor elements.

As shown in FIG. 20, one end of each of the plurality of reactance elements 361 (for example, the plurality of capacitor elements 501) is connected to the connection point 30s. The other end of each of the plurality of reactance elements 361 is connected to a first contact 71t1 of a relay switch 71s of a corresponding relay among the plurality of relays 71. A second contact 71t2 of the relay switch 71s of each of the plurality of relays 71 is connected to the ground.

As shown in FIG. 20, the matching circuit 34 includes a drive circuit 34d and a control circuit 34c. The drive circuit 34d shown in FIG. 20 has the same configuration as that shown in FIG. 8, but may have other configurations shown in FIGS. 7 and 9.

The drive circuit 34d shown in FIG. 20 is configured to set the state (open state or closed state) of the relay switch 71s of each of the plurality of relays 71 under the control of the control circuit 34c. The drive circuit 34d may include a plurality of drive circuits 71d that individually control the states of the relay switches 71s of the plurality of relays 71. The drive circuits 71d may be provided as elements of the plurality of relays 71. Each of the drive circuits 71d is configured to generate a DC voltage signal for closing the relay switch 71s of a corresponding relay among the plurality of relays 71.

As shown in FIG. 20, the relay coils 71c of the plurality of relays 71 may be floating from the ground with respect to radio frequencies. In this case, each of the plurality of drive circuits 71d includes a transformer 711, a pulse generator 71p, and a DC voltage generation circuit 71g. A transistor 71_{Tr} is connected to the primary coil of the transformer 71_{T1}. The pulse generator 71p generates a radio-frequency pulse and supplies the same to a control terminal of the transistor 71_{Tr}. A frequency of the radio-frequency pulse is, for example, 160 kHz. When the radio-frequency pulse is applied to the transistor 71_{Tr}, a pulse current is generated in the secondary coil of the transformer 71_{T1}.

The DC voltage generation circuit 71g is connected between the corresponding relay coil 71c and the secondary coil of the transformer 71_{T1}. The DC voltage generation circuit 71g includes a capacitor 71_{Cw}, a first diode 71_{D1}, and a second diode 71_{D2}. One end of the secondary coil is connected to one end of the corresponding relay coil 71c via the second diode 71_{D2}. An anode of the second diode 71_{D2} is connected to one end of the secondary coil, and a cathode of the second diode 71_{D2} is connected to one end of the corresponding relay coil 71c.

The capacitor 71_{Cw} and the first diode 71_{D1} are connected in parallel between the corresponding relay coil 71c and the secondary coil of the transformer 71_{T1}. A cathode of the first diode 71_{D1} is connected to one end of the corresponding relay coil 71c and the cathode of the second diode 71_{D2}. An anode of the first diode 71_{D1} is connected to the other end of the corresponding relay coil 71c and the other end of the secondary coil.

The pulse current generated in the secondary coil charges the capacitor 71_{Cw} via the second diode 71_{D2}. When the radio-frequency pulse is in an OFF state, a return current generated by the inductance component of the relay coil 71c flows through the first diode 71_{D1}. Thus, a DC voltage is generated in the capacitor 71_{Cw}, and a DC voltage signal is applied to the relay coil 71c. As a result, the relay switch 71s is set to the closed state.

As shown in FIG. 20, the matching circuit 34 includes a common resistor 34_{Ru} (shunt resistor) and a plurality of resistors 34_{Rd}. One end of the common resistor 34_{Ru} is connected to a DC power supply that outputs a voltage Vdd. Each of the plurality of resistors 34_{Ra} is connected between the first contact 71t1 of each of the plurality of relays 71 and the other end of the common resistor 34_{Ru}. The other end of the common resistor 34_{Ru} is connected to an A/D conversion terminal of the control circuit 34c via an amplifier Au. A capacitor 34_{Cf} for bypassing a radio-frequency current is connected between the electrical path, which is formed between the other end of the common resistor 34_{Ru} and the amplifier Au, and the ground.

A voltage Vu is generated across the common resistor 34_{Ru}, as shown in Formula (F3) below.

$$Vu = ( Ru / ( Ru + Rd / N ) ) \times Vdd \qquad ( F3 )$$

Here, Ru is the resistance value of the common resistor 34_{Ru}, Rd is the resistance value of each of the plurality of resistors 34_{Rd}, and N is the number of relays 71 kept in the closed state.

As shown in Formula (F3) above, the voltage Vu increases along with an increase in the number of relays 71 kept in the closed state. The voltage Vu is inputted to the A/D conversion terminal of the control circuit 34c via the amplifier Au. The control circuit 34c generates a digital value obtained by A/D conversion of the voltage inputted to the A/D conversion terminal. The control circuit 34c pre-stores an ideal value of the digital value corresponding to the number of relays 71 kept in the closed state. The control circuit 34c detects a failure of any of the plurality of relays 71 by comparing the digital value obtained by A/D conversion of the voltage inputted to the A/D conversion terminal with the ideal value corresponding to the number of relays 71 kept in the closed state at that time. For example, when the difference between the digital value obtained by A/D conversion and the ideal value corresponding to the number of relays 71 kept in the closed state at that time is greater than a threshold value, the control circuit 34c detects that the failure has occurred in any of the plurality of relays 71. In this way, the control circuit 34c may function as a detector configured to detect the failure of the plurality of relays 71.

The matching circuit 34 may further include a common resistor 34Rs (shunt resistor). One end of the common resistor 34Rs is connected to a DC power supply that outputs a voltage Vdd, and the other end of the common resistor 34Rs is connected to one end of the primary coil of the transformer 711. Further, the other end of the common resistor 34Rs is connected to another A/D conversion terminal of the control circuit 34c via an amplifier As. The DC power supply outputs a voltage Vdd to the common resistor 34Rs. The voltage Vs generated across the common resistor 34Rs varies depending on the number of the drive circuits 71d that have a failure on the primary side of the transformer 71_{T1}. Therefore, it is possible to detect a failure in any of the drive circuits 71d by comparing the digital value obtained by A/D conversion of the voltage inputted to another A/D conversion terminal of the control circuit 34c with the pre-stored value.

Although various exemplary embodiments have been described above, the present disclosure is not limited to the above-described exemplary embodiments, and various additions, omissions, substitutions, and modifications may be made. In addition, elements in different embodiments may be combined to form other embodiments.

Various exemplary embodiments included in the present disclosure are now described in [E1] to [E20] below.

### E1

A matching circuit includes:
a plurality of reactance elements connected to a supply line for supplying radio-frequency power for plasma generation;
a plurality of relays, wherein each of the plurality of relays includes a relay switch having a first contact connected to a corresponding reactance element among the plurality of reactance elements and a second contact connected to a ground, and a relay coil;
at least one diode connected in parallel to the relay coil of each of the plurality of relays and configured to rectify a radio-frequency current flowing through a parasitic capacitance between the relay coil and the corresponding reactance element; and
at least one capacitor connected in parallel to the relay coil of each of the plurality of relays and configured to generate a direct-current (DC) voltage applied to the relay coil in response to a current generated by rectifying the radio-frequency current with the at least one diode.

### E2

In the matching circuit of [E1] above, the relay switch has a characteristic of transitioning from a closed state to an open state when the DC voltage applied to the relay coil drops to a voltage level equal to or lower than a threshold voltage level, and wherein the at least one capacitor has an electrostatic capacitance set so that the DC voltage generated by the at least one capacitor has a voltage level higher than the threshold voltage level.

### E3

In the matching circuit of [E1] or [E2] above, each of the plurality of relays includes a drive circuit configured to apply a DC voltage signal to the relay coil when the relay switch is set to a closed state.

### E4

In the matching circuit of [E3] above, each of the plurality of relays further includes a choke coil connected between the drive circuit and the relay coil.

### E5

In the matching circuit of [E3] above, in each of the plurality of relays, the relay coil is provided so as to float from the ground with respect to radio frequencies, and
wherein the drive circuit includes:
   a transformer having a primary coil and a secondary coil;
   a pulse generator connected to the primary coil and configured to supply a radio-frequency pulse to the primary coil; and
   a DC voltage generation circuit including the at least one diode and the at least one capacitor, the DC voltage generation circuit being connected between the secondary coil and the relay coil and being configured to generate the DC voltage signal.

### E6

In the matching circuit of [E5] above, the at least one diode includes a first diode having a cathode connected to a first end of the relay coil, and a second end connected to a second end of the relay coil, and
wherein the DC voltage generation circuit further includes a second diode having a cathode connected to each of the first end of the relay coil and the cathode of the first diode, and an anode connected to a first end of the secondary coil.

### E7

In the matching circuit of [E5] above, the at least one capacitor includes:
a first capacitor having a first end connected to a first end of the relay coil; and
a second capacitor having a first end connected to each of a second end of the first capacitor and a first end of the secondary coil, and a second end connected to a second end of the relay coil, and
wherein the at least one diode includes:
a first diode having an anode connected to each of the second end of the relay coil and the second end of the second capacitor, and a cathode connected to the second end of the secondary coil; and
a second diode having an anode connected to each of the cathode of the first diode and the second end of the secondary coil, and a cathode connected to the first end of the relay coil and the first end of the first capacitor.

### E8

In the matching circuit of any one of [E1] to [E7] above, the supply line is configured as a transmission line, which is a distributed constant line having a constant impedance.

### E9

In the matching circuit of [E8] above, the supply line is a microstrip line.

### E10

The matching circuit of [E1] to [E9] above further includes:
a common resistor connected to a DC power supply;
a plurality of resistors, each of the plurality of resistors being connected between the common resistor and the first contact of the relay switch of a corresponding relay among the plurality of relays; and
a detector configured to detect a failure of the plurality of relays based on a voltage at the common resistor.

### E11

In the matching circuit of any one of [E1] to [E10] above, the plurality of reactance elements are a plurality of capacitor elements.

### E12

In the matching circuit of [E11] above further includes:
a capacitor plate connected to the supply line;
a printed circuit board having a plurality of capacitor patterns and configured to mount the plurality of relays thereon; and
a plurality of dielectric members, each of the plurality of dielectric members being arranged between a corresponding capacitor pattern among the plurality of capacitor patterns and the capacitor plate,
wherein each of the plurality of capacitor elements is composed of the capacitor plate, the corresponding capacitor pattern among the plurality of capacitor patterns, and a dielectric member among the plurality of dielectric members, which is arranged between the capacitor plate and the corresponding capacitor pattern.

### E13

In the matching circuit of [E12] above, the plurality of capacitor elements have the same electrostatic capacitance.

### E14

In the matching circuit of [E11] above, each of the plurality of capacitor elements includes:
first electrodes having different areas; and
a second electrode common to the plurality of capacitor elements and arranged to face each of the first electrodes of the plurality of capacitor elements via the plurality of dielectric members, and
wherein an electrostatic capacitance of each of the plurality of capacitor elements satisfies Cₘ=0.5×Cₘ₋₁, where Cₘ is an electrostatic capacitance of a m-th capacitor element among first to M-th capacitor elements which are the plurality of capacitor elements.

### E15

In the matching circuit of any one of [E1] to [E11] above, the plurality of reactance elements are a plurality of inductor elements.

### E16

The matching circuit of [E15] above further includes:
a conductor pattern,
wherein the relay switch of each of the plurality of relays is connected in parallel between the conductor pattern and the ground so that the conductor pattern is divided into the inductor elements.

### E17

In the matching circuit of any one of [E1] to [E10] above, the plurality of reactance elements include a plurality of capacitor elements and a plurality of inductor elements.

### E18

A plasma processing apparatus includes:
a chamber;
a radio-frequency power supply configured to be capable of changing a frequency of output radio-frequency power;
an introducer arranged to introduce electromagnetic waves into a plasma generation region inside the chamber;
a resonator having a feeding portion which is an inlet of the electromagnetic waves and including a waveguide for propagating the electromagnetic waves to the introducer; and
a coupler including an input portion for the radio-frequency power and the matching circuit of any one of [E11] to [E14] above and connected between the radio-frequency power supply and the resonator,
wherein the resonator includes:
   an inner peripheral portion extending around a central axis of the chamber and the resonator;
   an outer peripheral portion extending around the central axis;
   the waveguide having an alternately-folded layer structure between the inner peripheral portion and the outer peripheral portion;
   an upper portion located in an uppermost layer of the alternately-folded layer structure and having an upper end at the outer peripheral portion; and
   a lower portion located in a lowermost layer of the alternately-folded layer structure and having a lower end coupled to the introducer, and
wherein the feeding portion is arranged inside the upper end and at the upper portion, and is provided at a position outside a radial position where an impedance on a load side from the feeding portion is 50Ω.

### E19

A plasma processing apparatus includes:
a chamber;
a radio-frequency power supply configured to be capable of changing a frequency of output radio-frequency power;
an introducer arranged to introduce electromagnetic waves into a plasma generation region inside the chamber;
a resonator having a feeding portion which is an inlet of the electromagnetic waves and including a waveguide for propagating the electromagnetic waves to the introducer; and
a coupler including an input portion for the radio-frequency power and the matching circuit of [E15] or [E16] above and connected between the radio-frequency power supply and the resonator,
wherein the resonator includes:
   an inner peripheral portion extending around a central axis of the chamber and the resonator;
   an outer peripheral portion extending around the central axis;
   the waveguide having an alternately-folded layer structure between the inner peripheral portion and the outer peripheral portion;
   an upper portion located in an uppermost layer of the alternately-folded layer structure and having an upper end at the outer peripheral portion; and
   a lower portion located in a lowermost layer of the alternately-folded layer structure and having a lower end coupled to the introducer, and
wherein the feeding portion is arranged inside the upper end and at the upper portion, and is provided at a position inward of a radial position where an impedance on a load side from the feeding portion is 50Ω.

### E20

A plasma processing apparatus includes:
a chamber;
a radio-frequency power supply configured to be capable of changing a frequency of output radio-frequency power;
an introducer arranged to introduce electromagnetic waves into a plasma generation region in the chamber;
a resonator having a feeding portion which is an inlet of the electromagnetic waves and including a waveguide for propagating the electromagnetic waves to the introducer; and
a coupler including an input portion for the radio-frequency power and the matching circuit of [E17] above and connected between the radio-frequency power supply and the resonator,
wherein the resonator includes:
   an inner peripheral portion extending around a central axis of the chamber and the resonator;
   an outer peripheral portion extending around the central axis;
   the waveguide having an alternately-folded layer structure between the inner peripheral portion and the outer peripheral portion;
   an upper portion located in an uppermost layer of the alternately-folded layer structure and having an upper end at the outer peripheral portion; and
   a lower portion located in a lowermost layer of the alternately-folded layer structure and having a lower end coupled to the introducer, and
wherein the feeding portion is arranged inside the upper end and at the upper portion, and is provided at a radial position where an impedance on a load side from the feeding portion is 50Ω.

According to one exemplary embodiment, it is possible to suppress a relay switch, to which a radio-frequency current is supplied, from being unintentionally changed from a closed state to an open state in a matching circuit of a plasma processing apparatus.

From the foregoing, it will be understood that various embodiments of the present disclosure have been described herein for purposes of description, and that various modifications may be made without departing from the scope and spirit of the present disclosure. Accordingly, the various embodiments disclosed herein are not intended to be limitative, and the true scope and spirit thereof are defined by the appended claims.

What is claimed is:

1. A matching circuit, comprising:
a plurality of reactance elements connected to a supply line for supplying radio-frequency power for plasma generation;
a plurality of relays, wherein each of the plurality of relays includes a relay switch having a first contact connected to a corresponding reactance element among the plurality of reactance elements and a second contact connected to a ground, and a relay coil;
at least one diode connected in parallel to the relay coil of each of the plurality of relays and configured to rectify a radio-frequency current flowing through a parasitic capacitance between the relay coil and the corresponding reactance element; and
at least one capacitor connected in parallel to the relay coil of each of the plurality of relays and configured to generate a direct-current (DC) voltage applied to the relay coil in response to a current generated by rectifying the radio-frequency current with the at least one diode.

2. The matching circuit of claim 1, wherein the relay switch has a characteristic of transitioning from a closed state to an open state when the DC voltage applied to the relay coil drops to a voltage level equal to or lower than a threshold voltage level, and
wherein the at least one capacitor has an electrostatic capacitance which is set so that the DC voltage generated by the at least one capacitor has a voltage level higher than the threshold voltage level.

3. The matching circuit of claim 1, wherein each of the plurality of relays includes a drive circuit configured to apply a DC voltage signal to the relay coil when the relay switch is set to a closed state.

4. The matching circuit of claim 3, wherein each of the plurality of relays further includes a choke coil connected between the drive circuit and the relay coil.

5. The matching circuit of claim 3, wherein in each of the plurality of relays, the relay coil is provided so as to float from the ground with respect to radio frequencies, and
wherein the drive circuit includes:
a transformer having a primary coil and a secondary coil;
a pulse generator connected to the primary coil and configured to supply a radio-frequency pulse to the primary coil; and
a DC voltage generation circuit including the at least one diode and the at least one capacitor, the DC voltage generation circuit being connected between the secondary coil and the relay coil and being configured to generate the DC voltage signal.

6. The matching circuit of claim 5, wherein the at least one diode includes a first diode having a cathode connected to a first end of the relay coil, and a second end connected to a second end of the relay coil, and
wherein the DC voltage generation circuit further includes a second diode having a cathode connected to each of the first end of the relay coil and the cathode of the first diode, and an anode connected to a first end of the secondary coil.

7. The matching circuit of claim 5, wherein the at least one capacitor includes:
a first capacitor having a first end connected to a first end of the relay coil; and
a second capacitor having a first end connected to each of a second end of the first capacitor and a first end of the secondary coil, and a second end connected to a second end of the relay coil,
wherein the at least one diode includes:
a first diode having an anode connected to each of the second end of the relay coil and the second end of the second capacitor, and a cathode connected to the second end of the secondary coil; and
a second diode having an anode connected to each of the cathode of the first diode and the second end of the secondary coil, and a cathode connected to the first end of the relay coil and the first end of the first capacitor.

8. The matching circuit of claim 1, wherein the supply line is configured as a transmission line, which is a distributed constant line having a constant impedance.

9. The matching circuit of claim 8, wherein the supply line is a microstrip line.

10. The matching circuit of claim 1, further comprising:
a common resistor connected to a DC power supply;
a plurality of resistors, each of the plurality of resistors being connected between the common resistor and the first contact of the relay switch of a corresponding relay among the plurality of relays; and
a detector configured to detect a failure of the plurality of relays based on a voltage at the common resistor.

11. The matching circuit of claim 1, wherein the plurality of reactance elements are a plurality of capacitor elements.

12. The matching circuit of claim 11, further comprising:
a capacitor plate connected to the supply line;
a printed circuit board having a plurality of capacitor patterns and configured to mount the plurality of relays thereon; and
a plurality of dielectric members, each of the plurality of dielectric members being arranged between a corresponding capacitor pattern among the plurality of capacitor patterns and the capacitor plate,
wherein each of the plurality of capacitor elements is composed of the capacitor plate, the corresponding capacitor pattern among the plurality of capacitor patterns, and a dielectric member among the plurality of dielectric members, which is arranged between the capacitor plate and the corresponding capacitor pattern.

13. The matching circuit of claim 12, wherein the plurality of capacitor elements have a same electrostatic capacitance.

14. The matching circuit of claim 11, wherein each of the plurality of capacitor elements includes:
first electrodes having different areas; and
a second electrode common to the plurality of capacitor elements and arranged to face each of the first electrodes of the plurality of capacitor elements via the plurality of dielectric members, and
wherein an electrostatic capacitance of each of the plurality of capacitor elements satisfies Cₘ=0.5×Cₘ₋₁, where Cₘ is an electrostatic capacitance of an m-th capacitor element among first to M-th capacitor elements which are the plurality of capacitor elements.

15. The matching circuit of claim 1, wherein the plurality of reactance elements are a plurality of inductor elements.

16. The matching circuit of claim 15, further comprising:
a conductor pattern,
wherein the relay switch of each of the plurality of relays is connected in parallel between the conductor pattern and the ground so that the conductor pattern is divided into the plurality of inductor elements.

17. The matching circuit of claim 1, wherein the plurality of reactance elements include a plurality of capacitor elements and a plurality of inductor elements.

18. A plasma processing apparatus, comprising:
a chamber;
a radio-frequency power supply configured to be capable of changing a frequency of output radio-frequency power;
an introducer arranged to introduce electromagnetic waves into a plasma generation region inside the chamber;
a resonator having a feeding portion which is an inlet of the electromagnetic waves and including a waveguide for propagating the electromagnetic waves to the introducer; and
a coupler including an input portion for the radio-frequency power and the matching circuit of claim 11 and connected between the radio-frequency power supply and the resonator,
wherein the resonator includes:
an inner peripheral portion extending around a central axis of the chamber and the resonator;
an outer peripheral portion extending around the central axis;
the waveguide having an alternately-folded layer structure between the inner peripheral portion and the outer peripheral portion;
an upper portion located in an uppermost layer of the alternately-folded layer structure and having an upper end at the outer peripheral portion; and
a lower portion located in a lowermost layer of the alternately-folded layer structure and having a lower end coupled to the introducer, and
wherein the feeding portion is arranged inward of the upper end and at the upper portion, and is provided at a position outside a radial position where an impedance on a load side from the feeding portion is 50Ω.

19. A plasma processing apparatus, comprising:
a chamber;
a radio-frequency power supply configured to be capable of changing a frequency of output radio-frequency power;
an introducer arranged to introduce electromagnetic waves into a plasma generation region inside the chamber;
a resonator having a feeding portion which is an inlet of the electromagnetic waves and including a waveguide for propagating the electromagnetic waves to the introducer; and
a coupler including an input portion for the radio-frequency power and the matching circuit of claim 15 and connected between the radio-frequency power supply and the resonator,
wherein the resonator includes:
an inner peripheral portion extending around a central axis of the chamber and the resonator;
an outer peripheral portion extending around the central axis;
the waveguide having an alternately-folded layer structure between the inner peripheral portion and the outer peripheral portion;
an upper portion located in an uppermost layer of the alternately-folded layer structure and having an upper end at the outer peripheral portion; and
a lower portion located in a lowermost layer of the alternately-folded layer structure and having a lower end coupled to the introducer, and
wherein the feeding portion is arranged inward of the upper end and at the upper portion, and is provided at a position inward of a radial position where an impedance on a load side from the feeding portion is 50Ω.

20. A plasma processing apparatus, comprising:
a chamber;
a radio-frequency power supply configured to be capable of changing a frequency of output radio-frequency power;
an introducer arranged to introduce electromagnetic waves into a plasma generation region in the chamber;
a resonator having a feeding portion which is an inlet of the electromagnetic waves and including a waveguide for propagating the electromagnetic waves to the introducer; and
a coupler including an input portion for the radio-frequency power and the matching circuit of claim 17 and connected between the radio-frequency power supply and the resonator,
wherein the resonator includes:
an inner peripheral portion extending around a central axis of the chamber and the resonator;
an outer peripheral portion extending around the central axis;
the waveguide having an alternately-folded layer structure between the inner peripheral portion and the outer peripheral portion;
an upper portion located in an uppermost layer of the alternately-folded layer structure and having an upper end at the outer peripheral portion; and
a lower portion located in a lowermost layer of the alternately-folded layer structure and having a lower end coupled to the introducer, and
wherein the feeding portion is arranged inward of the upper end and at the upper portion, and is provided at a radial position where an impedance on a load side from the feeding portion is 50Ω.
